(19) United States
(12) Patent Application Publication
(10) Pub. No.: US 2026/0313268 A1
(43) Pub. Date: Oct. 8, 2026

(54) METHOD OF OPERATING IMAGE SENSOR AND IMAGE SENSOR PERFORMING THE SAME

(71) Applicant: Samsung Electronics Co., Ltd., Suwon-si (KR)

(72) Inventors: Jaeseong Yu, Suwon-si (KR); Haesick Sul, Suwon-si (KR); Taeshick Wang, Suwon-si (KR); Sehwan Yun, Suwon-si (KR)

(73) Assignee: Samsung Electronics Co., Ltd., Suwon-si (KR)

(21) Appl. No.: 19/368,296

(22) Filed: Oct. 24, 2025

(30) Foreign Application Priority Data
Apr. 2, 2025 (KR) 10-2025-0042647

(51) Int. Cl. H04N 25/78; H04N 25/57; H04N 25/704; H04N 25/778; H10F 39/00

(52) U.S. Cl. CPC H04N 25/78; H04N 25/57; H04N 25/704; H04N 25/778; H10F 39/8063; H10F 39/813

(57) ABSTRACT

In a method of operating an image sensor, first reset signals are outputted in a first reset period. first digital signals are outputted based on the first reset signals and a first pixel signals in a first signal period. Second reset signals are outputted in a second reset period. Second digital signals are outputted based on the second reset signals and second pixel signals in a second signal period. Third digital signals are outputted based on the second reset signals and third pixel signals in a third signal period. An AF operation is performed based on the first digital signals and the second digital signals. An HDR merging operation is performed based on the first digital signals, second digital signals, and the third digital signals.

### CROSS-REFERENCE TO RELATED APPLICATIONS

This present application claims priority to and the benefit under 35 USC § 119(a)-(d) of Korean Patent Application No. 10-2025-0042647 filed on Apr. 2, 2025 in the Korean Intellectual Property Office (KIPO), the entire disclosure of which is incorporated herein by reference.

### FIELD

Example embodiments relate generally to image sensors, and more particularly to methods of operating image sensors and image sensors performing the methods.

### BACKGROUND

Complementary metal oxide semiconductor (CMOS) image sensors are solid-state sensing devices that use CMOS. CMOS image sensors have lower manufacturing costs and/or lower power consumption compared with charge-coupled device (CCD) image sensors. Thus, CMOS image sensors are used for various electronic appliances including portable devices such as, for example, smartphones and digital cameras.

A pixel array included in a CMOS image sensor may include a photoelectric conversion element such as a photodiode in each pixel. The photoelectric conversion element generates an electrical signal that varies based on the quantity of incident light. The CMOS image sensor processes electrical signals to synthesize an image. With increasing demand for high-resolution images, there is a growing need to reduce the size of the individual pixels constituting the CMOS image sensor. However, as pixel miniaturization advances, it becomes more difficult to properly sense incoming light, and interference between increasingly dense components may lead to the generation of noise. There is also increasing demand for additional functions such as enhanced image quality and auto focus (AF).

### SUMMARY

Example embodiments of the present disclosure provide a method of operating an image sensor capable of performing both an auto focus (AF) operation and a high dynamic range (HDR) merging operation.

Example embodiments of the present disclosure provide an image sensor performing the method of operating the image sensor.

According to example embodiments, in a method of operating an image sensor including a pixel array including a plurality of first pixels, a plurality of second pixels, a plurality of third pixels and a plurality of floating diffusions, a plurality of first reset signals are outputted by resetting the plurality of floating diffusions in a first reset period. A plurality of first digital signals are outputted based on the plurality of first reset signals and a plurality of first pixel signals in a first signal period. The plurality of first pixel signals are outputted from the plurality of first pixels. A plurality of second reset signals are outputted by resetting the plurality of floating diffusions in a second reset period. A plurality of second digital signals are outputted based on the plurality of second reset signals and a plurality of second pixel signals in a second signal period. The plurality of second pixel signals are outputted from the plurality of second pixels. A plurality of third digital signals are outputted based on the plurality of second reset signals and a plurality of third pixel signals in a third signal period. The plurality of third pixel signals are outputted from the plurality of second pixels and the plurality of third pixels. An auto focus (AF) operation is performed based on the plurality of first digital signals and the plurality of second digital signals. A high dynamic range (HDR) merging operation is performed based on the plurality of first digital signals, the plurality of second digital signals, and the plurality of third digital signals. At least one of the plurality of first pixels, at least one of the plurality of second pixels, and at least one of the plurality of third pixels are configured to share one of the plurality of floating diffusions.

According to example embodiments, an image sensor includes a pixel array, an analog-to-digital converter, an auto focus (AF) circuit and a high dynamic range (HDR) circuit. The pixel array includes a plurality of first pixels, a plurality of second pixels, a plurality of third pixels and a plurality of floating diffusions. The pixel array is configured to output a plurality of first reset signals by resetting the plurality of floating diffusions in a first reset period, to output a plurality of first analog pixel signals in a first signal period, to output a plurality of second reset signals by resetting the plurality of floating diffusions in a second reset period, to output a plurality of second analog pixel signals in a second signal period, and to output a plurality of third analog pixel signals in a third signal period. The plurality of first analog pixel signals are outputted from the plurality of first pixels, the plurality of second analog pixel signals are outputted from the plurality of second pixels, and the plurality of third analog pixel signals are outputted from the plurality of second pixels and the plurality of third pixels. The analog-to-digital converter is configured to output a plurality of first digital signals based on the plurality of first analog reset signals and the plurality of first analog pixel signals, to output a plurality of second digital signals based on the plurality of second analog reset signals and the plurality of second analog pixel signals, and to output a plurality of third digital signals based on the plurality of second analog reset signals and the plurality of third analog pixel signals. The AF circuit is configured to perform an AF operation based on the plurality of first digital signals and the plurality of second digital signals. The HDR circuit is configured to perform an HDR merging operation based on the plurality of first digital signals, the plurality of second digital signals, and the plurality of third digital signals. At least one of the plurality of first pixels, at least one of the plurality of second pixels, and at least one of the plurality of third pixels are configured to share one of the plurality of floating diffusions.

In the method of operating image sensor and the image sensor according to example embodiments, all-pixel auto focus (AF) operation and high dynamic range (HDR) merging operation may be performed simultaneously by using reset-signal-reset-signal-signal (RSRSS) readout. During the HDR merging operation, images with various area ratios may be synthesized. In addition, by using a high conversion gain, a read noise (RN) may be reduced, smaller pixels may be implemented, and the frame rate may be increased up to twice the frame rate of conventional intra-scene dual conversion gain (iDCG).

### BRIEF DESCRIPTION OF THE DRAWINGS

Illustrative, non-limiting example embodiments will be more clearly understood from the following detailed description taken in conjunction with the accompanying drawings.

FIG. 1 is a flowchart illustrating a method of operating an image sensor according to example embodiments.

FIG. 2 is a block diagram illustrating an image sensor according to example embodiments.

FIG. 3 is a flowchart illustrating an example of outputting a plurality of first reset signals in a method of operating an image sensor according to example embodiments.

FIG. 4 is a diagram for describing an operation in FIG. 3.

FIG. 5 is a flowchart illustrating an example of outputting a plurality of first digital signals in a method of operating an image sensor according to example embodiments.

FIGS. 6A and 6B are diagrams for describing an operation in FIG. 5.

FIG. 7 is a flowchart illustrating an example of outputting a plurality of second reset signals in a method of operating an image sensor according to example embodiments.

FIG. 8 is a diagram for describing an operation in FIG. 7.

FIG. 9 is a flowchart illustrating an example of outputting a plurality of second digital signals in a method of operating an image sensor according to example embodiments.

FIGS. 10A and 10B are diagrams for describing an operation in FIG. 9.

FIG. 11 is a flowchart illustrating an example of outputting a plurality of third digital signals in a method of operating an image sensor according to example embodiments.

FIGS. 12A and 12B are diagrams for describing an operation in FIG. 11.

FIG. 13 is a timing diagram for describing operations in FIGS. 3, 5, 7, 9 and 11.

FIGS. 14A, 14B and 14C are diagrams illustrating examples of a pixel array and an analog-to-digital converter included in an image sensor according to example embodiments.

FIGS. 15A, 15B and 15C are diagrams illustrating examples of a pixel array and an analog-to-digital converter included in an image sensor according to example embodiments.

FIGS. 16A, 16B and 16C are diagrams illustrating examples of a pixel array and an analog-to-digital converter included in an image sensor according to example embodiments.

FIGS. 17A, 17B and 17C are diagrams illustrating examples of a pixel array and an analog-to-digital converter included in an image sensor according to example embodiments.

FIGS. 18A and 18B are diagrams for describing examples of performing an AF operation and performing an HDR merging operation in a method of operating an image sensor according to example embodiments.

FIG. 19 is a flowchart illustrating an example of performing an HDR merging operation in a method of operating an image sensor according to example embodiments.

FIG. 20 is a block diagram illustrating an example of an HDR circuit included in an image sensor according to example embodiments.

FIGS. 21A, 21B and 21C are diagrams illustrating examples of a pixel array and an analog-to-digital converter included in an image sensor according to example embodiments.

FIGS. 22A, 22B and 22C are diagrams illustrating examples of a pixel array and an analog-to-digital converter included in an image sensor according to example embodiments.

FIGS. 23A, 23B and 23C are diagrams illustrating examples of a pixel array and an analog-to-digital converter included in an image sensor according to example embodiments.

FIG. 24 is a block diagram illustrating an image sensor according to example embodiments.

### DETAILED DESCRIPTION

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

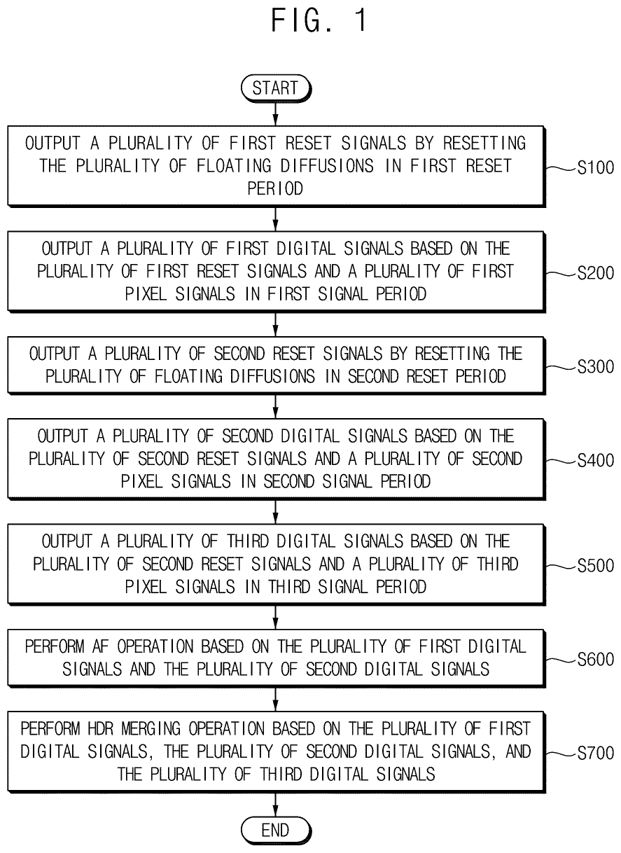

FIG. 1 is a flowchart illustrating a method of operating an image sensor according to example embodiments.

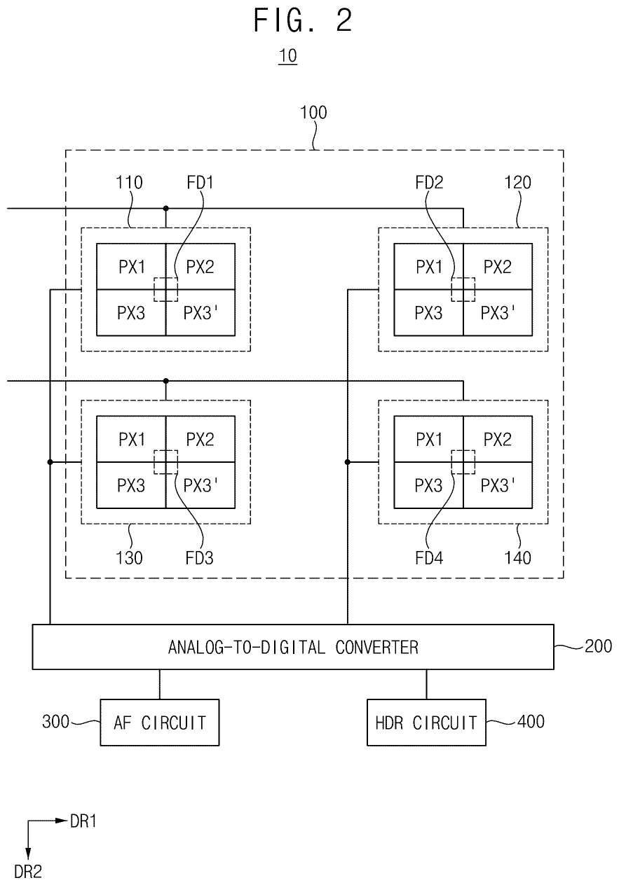

Referring to FIG. 1, a method of operating an image sensor according to example embodiments is performed by an image sensor including a pixel array, an analog-to-digital converter, an auto focus (AF) circuit, and a high dynamic range (HDR) circuit. The pixel array includes a plurality of first pixels, a plurality of second pixels, a plurality of third pixels, and a plurality of floating diffusions. An exemplary configuration of the image sensor will be described with reference to FIG. 2 and the like.

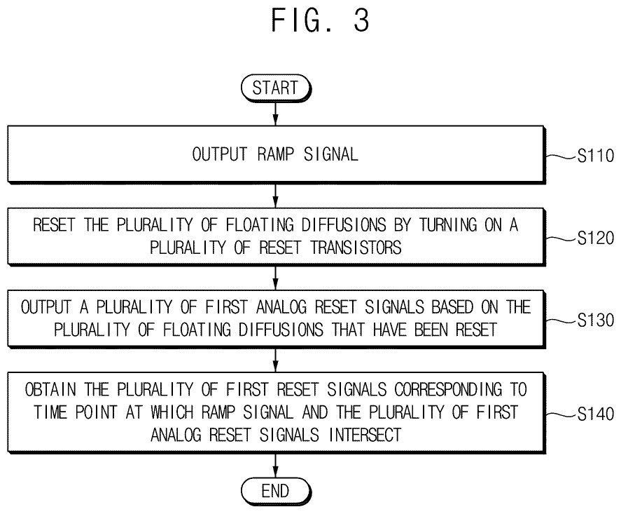

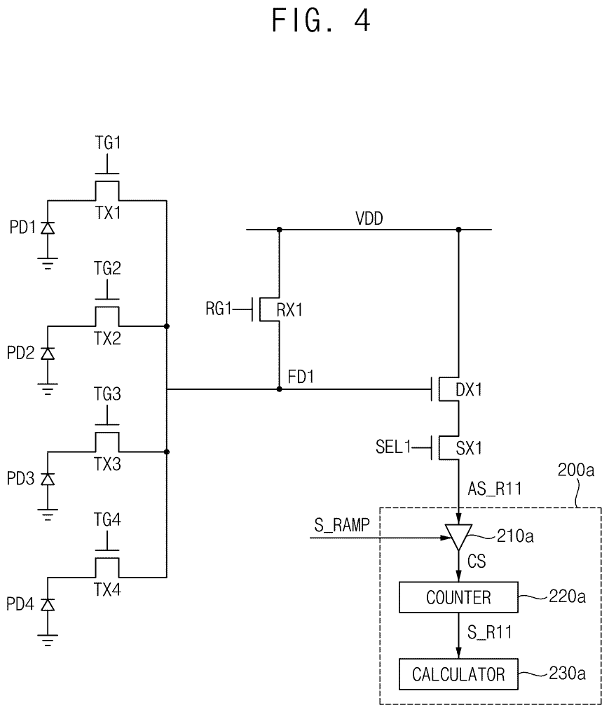

In the method of operating the image sensor according to example embodiments, a plurality of first reset signals are outputted by resetting the plurality of floating diffusions in a first reset period (operation S100). Operation S100 will be described with reference to FIGS. 3 and 4.

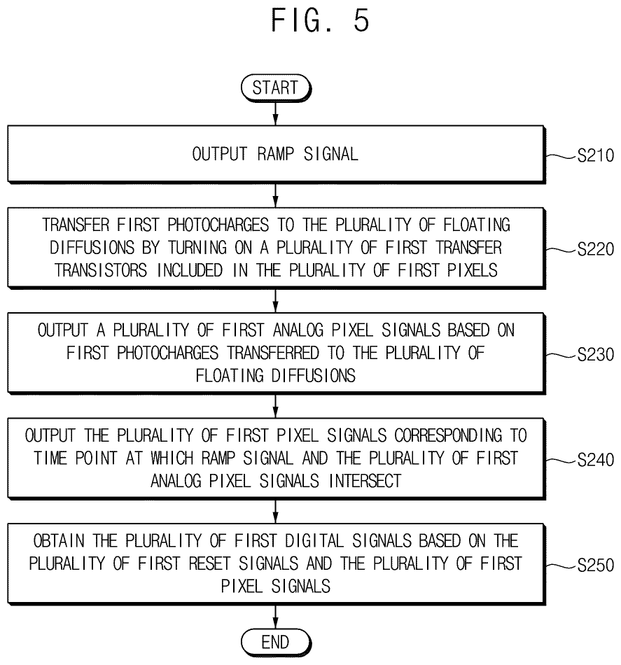

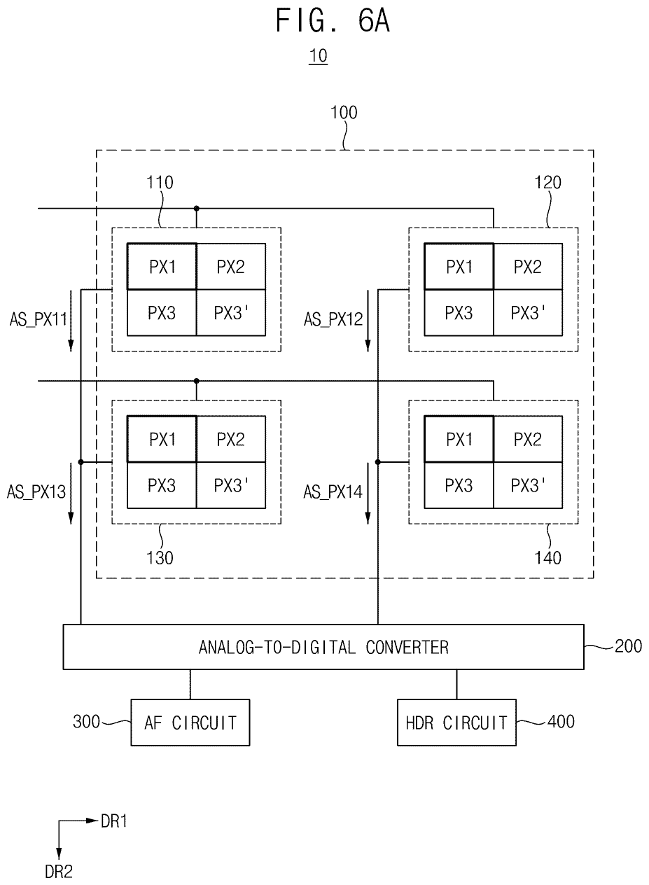

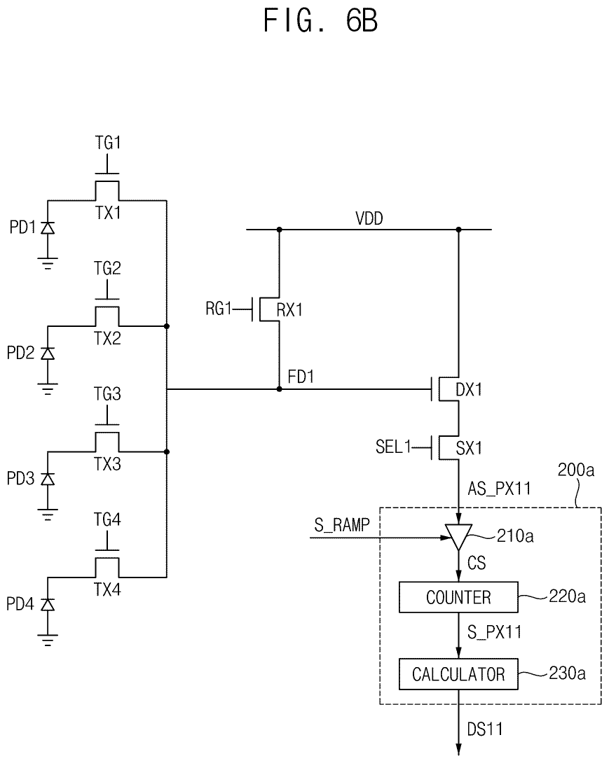

A plurality of first digital signals are outputted based on the plurality of first reset signals and a plurality of first pixel signals in a first signal period (operation S200). The plurality of first pixel signals are outputted from the plurality of first pixels. For example, differences between the plurality of first reset signals and the plurality of first pixel signals may be outputted as the plurality of first digital signals. Operation S200 will be described with reference to FIGS. 5, 6A, and 6B.

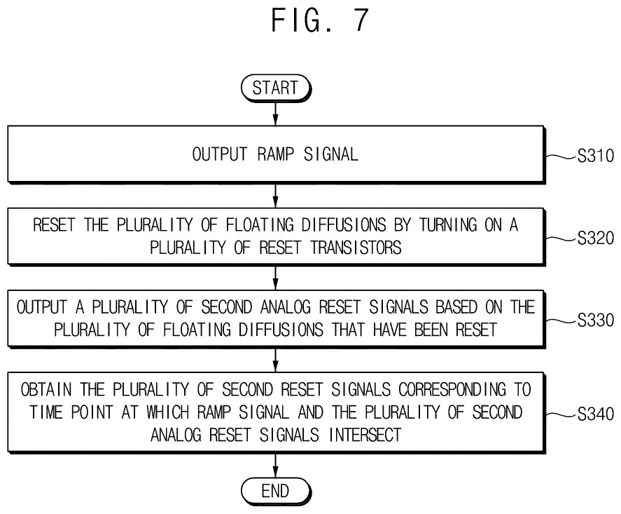

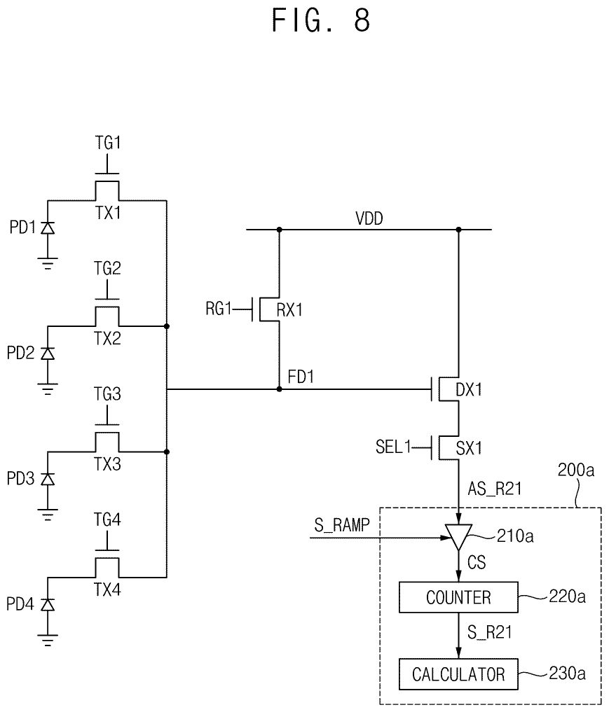

A plurality of second reset signals are outputted by resetting the plurality of floating diffusions in a second reset period (operation S300). Operation S300 will be described with reference to FIGS. 7 and 8.

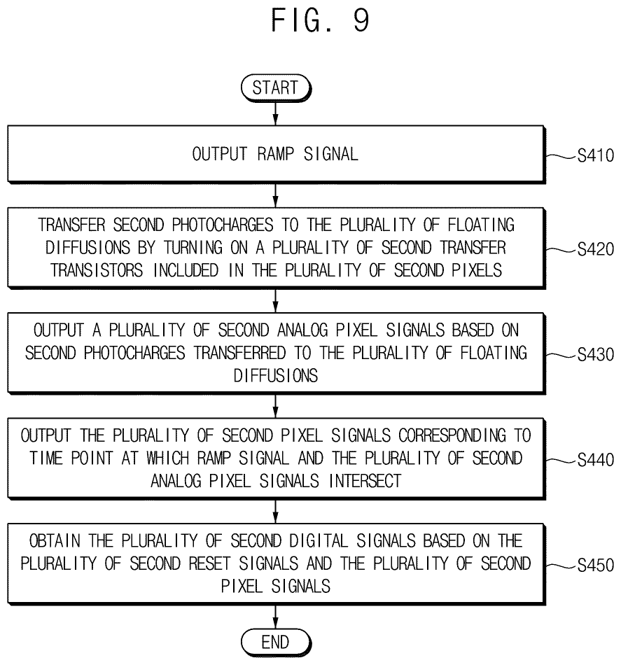

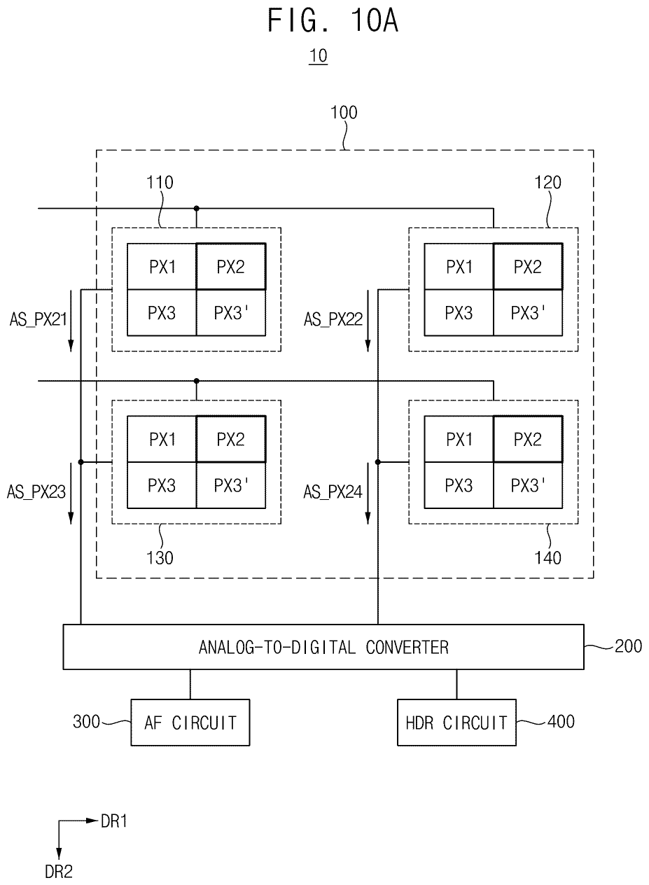

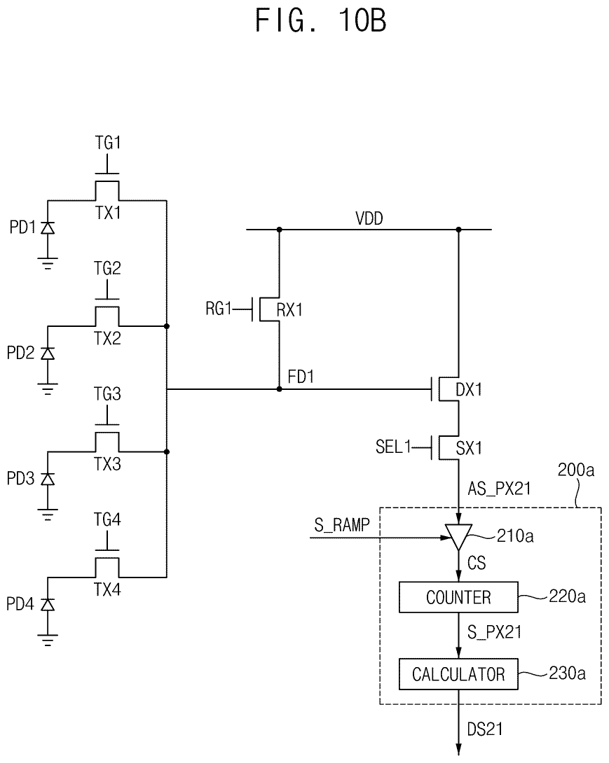

A plurality of second digital signals are outputted based on the plurality of second reset signals and a plurality of second pixel signals in a second signal period (operation S400). The plurality of second pixel signals are outputted from the plurality of second pixels. For example, differences between the plurality of second reset signals and the plurality of second pixel signals may be outputted as the plurality of second digital signals. Operation S400 will be described with reference to FIGS. 9, 10A, and 10B.

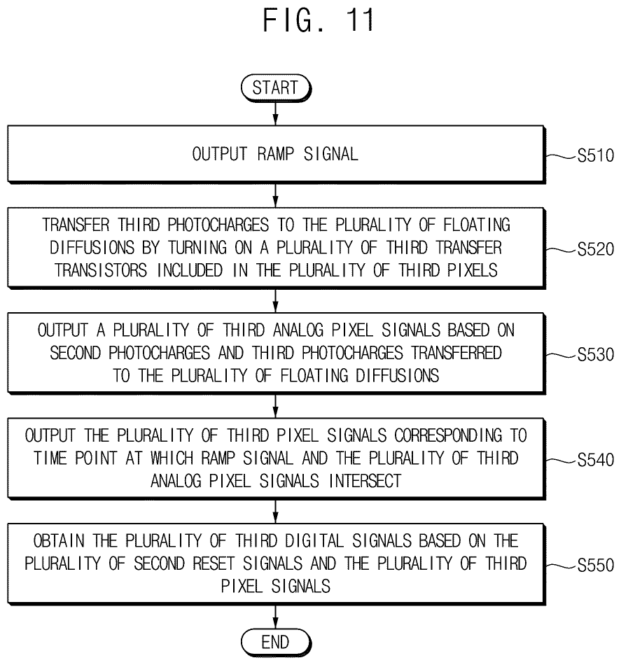

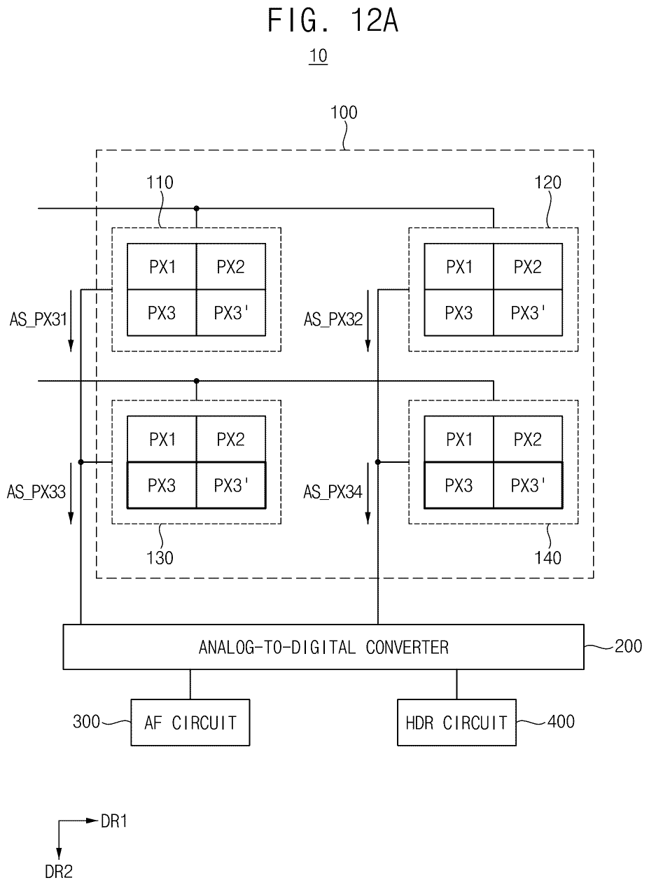

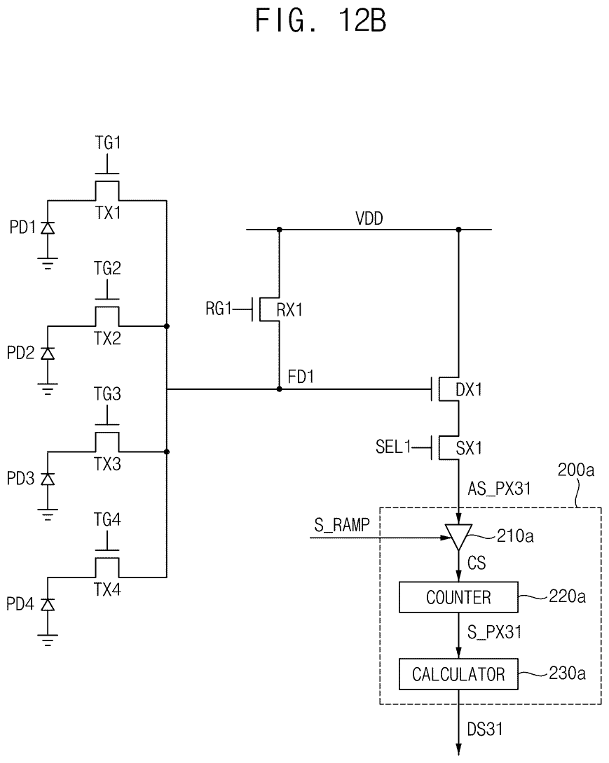

A plurality of third digital signals are outputted based on the plurality of second reset signals and a plurality of third pixel signals in a third signal period (operation S500). The plurality of third pixel signals are outputted from the plurality of second pixels and the plurality of third pixels. For example, differences between the plurality of second reset signals and the plurality of third pixel signals may be outputted as the plurality of third digital signals. Operation S500 will be described with reference to FIGS. 11, 12A, and 12B.

An AF operation is performed based on the plurality of first digital signals and the plurality of second digital signals (operation S600). Operation S600 will be described with reference to FIG. 2.

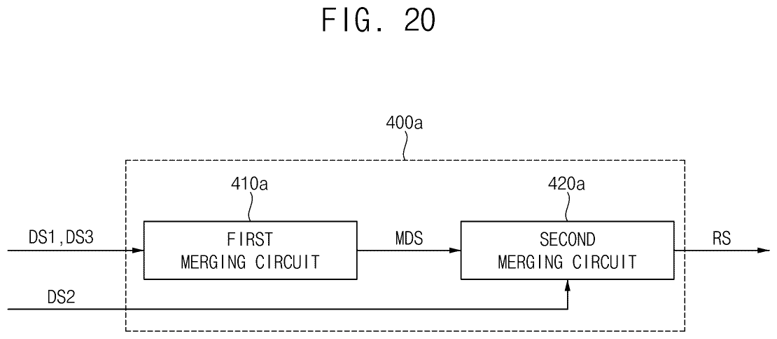

An HDR merging operation is performed based on the plurality of first digital signals, the plurality of second digital signals, and the plurality of third digital signals (operation S700). Operation S700 will be described with reference to FIGS. 19 and 20.

Conventional image sensors typically increase a dynamic range by reducing a read noise (RN). For example, conventional techniques for reducing RN include an intra-scene dual conversion gain (iDCG) and a dual slope gain (DSG). The iDCG effectively reduces RN and shows good performance in terms of dynamic range, but the iDCG requires a pair of analog-to-digital converters for implementation. A performance of the DSG in terms of dynamic range is inferior to the performance of the iDCG, but the DSG does not require a pair of analog-to-digital converters for implementation and has twice the frame rate of the iDCG.

In the method of operating image sensor and the image sensor according to example embodiments, all-pixel AF operation and HDR merging operation may be performed simultaneously by using reset-signal-reset-signal-signal (RSRSS) readout. During the HDR merging operation, images with various area ratios may be synthesized. In addition, by using a high conversion gain, the RN may be reduced, smaller pixels may be implemented, and the frame rate may be increased up to twice the frame rate of conventional iDCG.

FIG. 2 is a block diagram illustrating an image sensor according to example embodiments.

Referring to FIG. 2, an image sensor 10 according to example embodiments includes a pixel array 100, an analog-to-digital converter 200, an auto focus (AF) circuit 300, and a high dynamic range (HDR) circuit 400.

The pixel array 100 includes a plurality of pixel groups 110, 120, 130, and 140. The pixel group 110 may include a first pixel PX1, a second pixel PX2, a third pixel PX3, a third pixel PX3′, and a floating diffusions FD1. The pixel group 120 may include a first pixel PX1, a second pixel PX2, a third pixel PX3, a third pixel PX3′, and a floating diffusions FD2. The pixel group 130 may include a first pixel PX1, a second pixel PX2, a third pixel PX3, a third pixel PX3′, and a floating diffusions FD3. The pixel group 140 may include a first pixel PX1, a second pixel PX2, a third pixel PX3, a third pixel PX3′, and a floating diffusions FD4.

For example, in the pixel group 110, the first pixel PX1, the second pixel PX2, the third pixel PX3 and the third pixel PX3′ may share the floating diffusion FD1. Likewise, in the pixel group 120, the first pixel PX1, the second pixel PX2, the third pixel PX3 and the third pixel PX3′ may share the floating diffusion FD2. In the pixel group 130, the first pixel PX1, the second pixel PX2, the third pixel PX3 and the third pixel PX3′ may share the floating diffusion FD3. In the pixel group 140, the first pixel PX1, the second pixel PX2, the third pixel PX3 and the third pixel PX3′ may share the floating diffusion FD4.

The plurality of first pixels PX1, the plurality of second pixels PX2, the plurality of third pixels PX3 and the plurality of third pixels PX3′ may be arranged in a first direction DR1 and a second direction DR2 intersecting the first direction DR1. For example, the first direction DR1 may correspond to a row direction, and the second direction DR2 may correspond to a column direction.

For example, the plurality of first pixels PX1 may be red pixels, the plurality of second pixels PX2 and the plurality of third pixels PX3 may be green pixels, and the plurality of third pixels PX3′ may be blue pixels. However, example embodiments are not limited thereto, and color filters corresponding to the pixels may be variously determined.

FIG. 2 illustrates a case where the number of the plurality of first pixels PX1 is four, the number of the plurality of second pixels PX2 is four, the number of the plurality of third pixels PX3 is four and the number of the plurality of third pixels PX3′ is four, corresponding to four pixel groups arranged in a 2*2 pattern. However, example embodiments are not limited thereto, and the structure illustrated in FIG. 2 may be repeated in the first direction DR1 and the second direction DR2, and the positions and numbers of pixels may be variously determined.

The pixel array 100 outputs a plurality of first reset signals by resetting the plurality of floating diffusions in a first reset period, outputs a plurality of first analog pixel signals in a first signal period, outputs a plurality of second reset signals by resetting the plurality of floating diffusions in a second reset period, outputs a plurality of second analog pixel signals in a second signal period, and outputs a plurality of third analog pixel signals in a third signal period. The plurality of first analog pixel signals are outputted from the plurality of first pixels, the plurality of second analog pixel signals are outputted from the plurality of second pixels, and the plurality of third analog pixel signals are outputted from the plurality of second pixels and the plurality of third pixels. An exemplary operation of the pixel array 100 will be described with reference to FIGS. 4, 6A, 6B, 8, 10A, 10B, 12A, 12B, and 13.

The analog-to-digital converter 200 outputs a plurality of first digital signals based on the plurality of first analog reset signals and the plurality of first analog pixel signals, outputs a plurality of second digital signals based on the plurality of second analog reset signals and the plurality of second analog pixel signals, and outputs a plurality of third digital signals based on the plurality of second analog reset signals and the plurality of third analog pixel signals. An exemplary operation of the analog-to-digital converter 200 will be described with reference to FIGS. 4, 6A, 6B, 8, 10A, 10B, 12A, 12B, and 13.

The AF circuit 300 performs an AF operation based on the plurality of first digital signals and the plurality of second digital signals.

For example, the AF circuit 300 may perform the AF operation based on the first pixel PX1 and the second pixel PX2 in the pixel group 110. In other words, the AF operation may be performed based on the first digital signal outputted based on the first pixel PX1 and the second digital signal outputted based on the second pixel PX2 in pixel group 110. Likewise, the AF circuit 300 may perform the AF operation based on the first pixel PX1 and the second pixel PX2 in the pixel group 120, the AF circuit 300 may perform the AF operation based on the first pixel PX1 and the second pixel PX2 in the pixel group 130, and the AF circuit 300 may perform the AF operation based on the first pixel PX1 and the second pixel PX2 in the pixel group 140.

For example, if the first pixel PX1, the second pixel PX2, the third pixel PX3 and the third pixel PX3′ in the pixel group 110 share a microlens, the first pixel PX1, the second pixel PX2, the third pixel PX3 and the third pixel PX3′ in the pixel group 120 share a microlens, the first pixel PX1, the second pixel PX2, the third pixel PX3 and the third pixel PX3′ in the pixel group 130 share a microlens, the first pixel PX1, the second pixel PX2, the third pixel PX3 and the third pixel PX3′ in the pixel group 140 share a microlens, the AF circuit 300 may perform the AF operation for each of the microlenses. In other words, the AF circuit 300 may perform the all-pixel AF operation.

The HDR circuit 400 performs the HDR merging operation based on the plurality of first digital signals, the plurality of second digital signals, and the plurality of third digital signals. For example, the HDR circuit 400 may merge the plurality of first digital signals and the plurality of third digital signals, and then merge the merged signals and the second digital signals to output a plurality of result signals. An exemplary operation of the HDR circuit 400 will be described with reference to FIGS. 19 and 20.

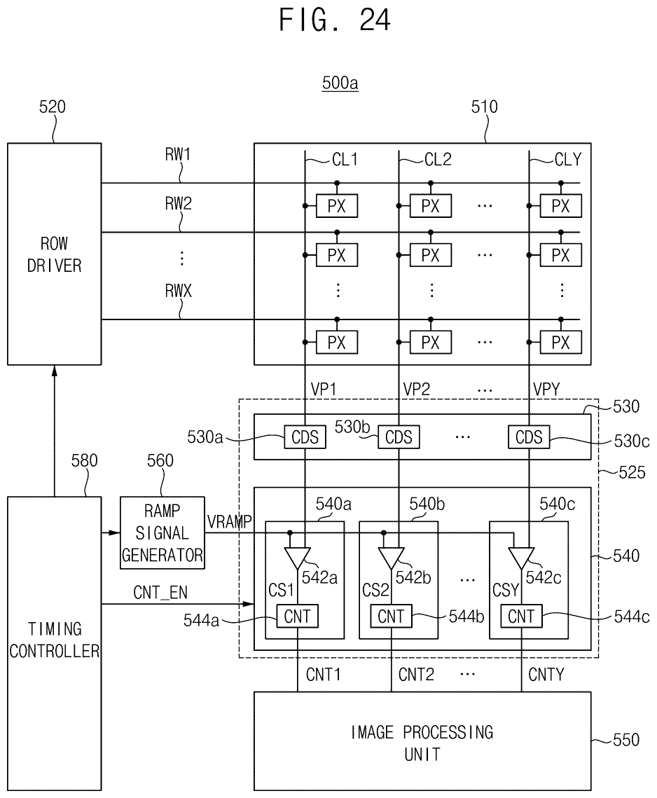

In some example embodiments, the image sensor 10 may further include various configurations for driving the pixel array 100. This will be described with reference to FIG. 24.

FIG. 3 is a flowchart illustrating an example of outputting a plurality of first reset signals in a method of operating an image sensor according to example embodiments.

Referring to FIG. 3, in outputting the plurality of first reset signals (operation S100), a ramp signal that decreases or increases at a constant slope may be outputted (operation S110). For example, the ramp signal may be outputted by a ramp signal generator (e.g. 560 in FIG. 24), and the ramp signal generator may be implemented to include a variable ramp current source for outputting the ramp signal.

The plurality of floating diffusions may be reset by turning on a plurality of reset transistors included in the pixel array (operation S120).

A plurality of first analog reset signals may be outputted based on the plurality of floating diffusions that have been reset (operation S130).

The plurality of first reset signals corresponding to a time point at which the ramp signal and the plurality of first analog reset signals intersect may be obtained (operation S140).

FIG. 4 is a diagram for describing an operation in FIG. 3.

Referring to FIG. 4, the first pixel (e.g., PX1 in FIG. 2) may include a first photodiode PD1 and a first transfer transistor TX1, the second pixel (e.g., PX2 in FIG. 2) may include a second photodiode PD2 and a second transfer transistor TX2, the third pixel (e.g., PX3 in FIG. 2) may include a third photodiode PD3 and a third transfer transistor TX3, and the third pixel (e.g., PX3′ in FIG. 2) may include a fourth photodiode PD4 and a fourth transfer transistor TX4.

For example, FIG. 4 illustrates only the first pixel PX1, the second pixel PX2, the third pixel PX3, and the third pixel PX3′ included in the pixel group 110 in the pixel array 100 in FIG. 2.

For example, the plurality of photodiodes PD1, PD2, PD3, and PD4 may perform a photoelectric conversion. In other words, in an integration mode, the plurality of photodiodes PD1, PD2, PD3, and PD4 may generate photocharges based on an incident light. For instance, when the image sensor is a complementary metal-oxide semiconductor (CMOS) image sensor, in the integration mode, a shutter of the CMOS image sensor may be opened such that charge carriers such as electron-hole pairs may be generated in the plurality of photodiodes PD1, PD2, PD3, and PD4 by the incident light, and information regarding an image of a subject may be obtained.

The first transfer transistor TX1 may be connected between the first photodiode PD1 and the first floating diffusion FD1, and may include a gate electrode receiving a first transfer control signal TG1. The second transfer transistor TX2 may be connected between the second photodiode PD2 and the first floating diffusion FD1, and may include a gate electrode receiving a second transfer control signal TG2. The third transfer transistor TX3 may be connected between the third photodiode PD3 and the first floating diffusion FD1, and may include a gate electrode receiving a third transfer control signal TG3. The fourth transfer transistor TX4 may be connected between the fourth photodiode PD4 and the first floating diffusion FD1, and may include a gate electrode receiving a fourth transfer control signal TG4.

For example, the first pixel PX1, the second pixel PX2, the third pixel PX3, and the third pixel PX3′ included in the pixel group 110 may share the first floating diffusion FD1, a first reset transistor RX1, a first drive transistor DX1, and a first selection transistor SX1.

For example, the first floating diffusion (or first floating diffusion node) FD1 may accumulate photocharges collected from the plurality of photodiodes PD1, PD2, PD3, and PD4 through the photoelectric conversion, and image information may be generated based on the amount of the photocharges transferred to the first floating diffusion FD1.

As described above, a structure in which the plurality of photodiodes PD1, PD2, PD3, and PD4 share a single floating diffusion may be referred to as a floating diffusion sharing structure. The first pixel PX1, the second pixel PX2, the third pixel PX3, and the third pixel PX3′ included in the pixel group 110 may have the floating diffusion sharing structure.

The first reset transistor RX1 may be connected between a power supply voltage VDD and the first floating diffusion FD1, and may include a gate electrode receiving a first reset control signal RG1.

The first drive transistor DX1 and the first selection transistor SX1 may be connected in series between the power supply voltage VDD and an analog-to-digital converter 200a. The first drive transistor DX1 may include a gate electrode connected to the first floating diffusion FD1, and the first selection transistor SX1 may include a gate electrode receiving a first selection control signal SEL1.

For example, the photocharges generated in the plurality of photodiodes PD1, PD2, PD3, and PD4 may be transferred to the first floating diffusion FD1 through the transfer transistors TX1, TX2, TX3, and TX4, respectively. The first floating diffusion FD1 may be reset by the first reset transistor RX1. The first drive transistor DX1 may function as a source follower buffer amplifier and may amplify a signal corresponding to the photocharges accumulated in the first floating diffusion FD1. The first pixel PX1, the second pixel PX2, the third pixel PX3, or the third pixel PX3′ included in the pixel group 110 may be selected by the first selection transistor SX1.

The analog-to-digital converter 200a may include a comparator 210a, a counter 220a, and a calculator 230a. The analog-to-digital converter 200a may be included in the analog-to-digital converter 200 in FIG. 2. Hereinafter, the descriptions repeated with or overlapping with descriptions of FIG. 2 will be omitted in the interest of brevity.

For example, a ramp signal S_RAMP that decreases or increases at a constant slope may be inputted to the comparator 210a. When the first reset control signal RG1 is activated and the first reset transistor RX1 is turned on, an electric potential of the first floating diffusion FD1 may be reset to the power supply voltage VDD. Based on the electric potential of the reset first floating diffusion FD1, a first analog reset signal AS_R11 may be outputted to the comparator 210a.

For example, the comparator 210a may compare the ramp signal S_RAMP with the first analog reset signal AS_R11 and may output a comparison signal CS to the counter 220a. The counter 220a may count an active interval (i.e., level transition time) of the comparison signal CS based on a count clock signal, and may output a first reset signal S_R11 to the calculator 230a. In other words, the counter 220a may output the first reset signal S_R11 corresponding to a time point at which the ramp signal S_RAMP and the first analog reset signal AS_R11 intersect to the calculator 230a.

Although not illustrated, the configurations and operations of the other pixel groups 120, 130, and 140 may be substantially the same as the configurations and operations of the pixel group 110. For example, each of the pixel groups 120, 130, and 140 may output the first reset signal, and the pixel groups 110, 120, 130, and 140 may output the plurality of first reset signals.

FIG. 5 is a flowchart illustrating an example of outputting a plurality of first digital signals in a method of operating an image sensor according to example embodiments.

Referring to FIG. 5, in outputting the plurality of first digital signals (operation S200), the ramp signal may be outputted (operation S210).

First photocharges may be transferred to the plurality of floating diffusions by turning on a plurality of first transfer transistors included in the plurality of first pixels (operation S220). The first photocharges may be generated in the plurality of first pixels.

A plurality of first analog pixel signals may be outputted based on the first photocharges transferred to the plurality of floating diffusions (operation S230).

The plurality of first pixel signals corresponding to a time point at which the ramp signal and the plurality of first analog pixel signals intersect may be outputted (operation S240).

The plurality of first digital signals may be obtained based on the plurality of first reset signals and the plurality of first pixel signals (operation S250).

FIGS. 6A and 6B are diagrams for describing an operation in FIG. 5.

Referring to FIG. 6A, first photocharges generated in the plurality of first pixels PX1 may be transferred to respective floating diffusions by turning on a plurality of first transfer transistors included in the plurality of first pixels PX1, and a plurality of first analog pixel signals AS_PX11, AS_PX12, AS_PX13, and AS_PX14 may be outputted to the analog-to-digital converter 200 based on the first photocharges transferred to the respective floating diffusions.

FIG. 6B illustrates only the first pixel PX1, the second pixel PX2, the third pixel PX3, and the third pixel PX3′ included in the pixel group 110 in the pixel array 100 in FIG. 6A, and represents an operation of generating the first analog pixel signal AS_PX11 and generating a first digital signal DS11 based on the first analog pixel signal AS_PX11.

Referring to FIG. 6B, a ramp signal S_RAMP that decreases or increases at a constant slope may be inputted to the comparator 210a. When the first transfer control signal TG1 is activated and the first transfer transistor TX1 is turned on, first photocharges generated in the first photodiode PD1 may be transferred to the first floating diffusion FD1. After the first transfer control signal TG1 is deactivated and the charge transfer operation is completed, the first analog pixel signal AS_PX11 may be outputted to the comparator 210a based on the first photocharges transferred to the first floating diffusion FD1.

For example, the comparator 210a may compare the ramp signal S_RAMP with the first analog pixel signal AS_PX11 and may output the comparison signal CS to the counter. The counter 220a may count the active interval (i.e., level transition time) of the comparison signal CS based on the count clock signal, and may output a first pixel signal S_PX11 to the calculator 230a. In other words, the counter 220a may output the first pixel signal S_PX11 corresponding to a time point at which the ramp signal S_RAMP and the first analog pixel signal AS_PX11 intersect to the calculator 230a.

For example, the calculator 230a may output the first digital signal DS11 based on the first reset signal (e.g., S_R11 in FIG. 4) and the first pixel signal S_PX11. For example, the calculator 230a may output a difference between the first reset signal S_R11 and the first pixel signal S_PX11 as the first digital signal DS11.

FIG. 7 is a flowchart illustrating an example of outputting a plurality of second reset signals in a method of operating an image sensor according to example embodiments.

Referring to FIG. 7, in outputting the plurality of second reset signals (operation S300), the ramp signal that decreases or increases at a constant slope may be outputted (operation S310).

The plurality of floating diffusions may be reset by turning on a plurality of reset transistors included in the pixel array (operation S320).

A plurality of second analog reset signals may be outputted based on the plurality of floating diffusions that have been reset (operation S330).

The plurality of second reset signals corresponding to a time point at which the ramp signal and the plurality of second analog reset signals intersect may be reset (operation S340).

FIG. 8 is a diagram for describing an operation in FIG. 7.

FIG. 8 illustrates only the first pixel PX1, the second pixel PX2, the third pixel PX3, and the third pixel PX3′ included in the pixel group 110 in the pixel array 100 in FIG. 2.

Referring to FIG. 8, the ramp signal S_RAMP that decreases or increases at a constant slope may be inputted to the comparator 210a. When the first reset control signal RG1 is activated and the first reset transistor RX1 is turned on, the electric potential of the first floating diffusion FD1 may be reset to the power supply voltage VDD. Based on the electric potential of the reset first floating diffusion FD1, a second analog reset signal AS_R21 may be outputted to the comparator 210a.

For example, the comparator 210a may compare the ramp signal S_RAMP with the second analog reset signal AS_R21 and may output the comparison signal CS to the counter 220a. The counter 220a may count the active interval (i.e., level transition time) of the comparison signal CS based on the count clock signal, and may output a second reset signal S_R21 to the calculator 230a. In other words, the counter 220a may output the second reset signal S_R21 corresponding to a time point at which the ramp signal S_RAMP and the second analog reset signal AS_R21 intersect to the calculator 230a.

Although not illustrated, the configurations and operations of the other pixel groups 120, 130, and 140 may be substantially the same as the configurations and operations of the pixel group 110. For example, each of the pixel groups 120, 130, and 140 may output the second reset signal, and the pixel groups 110, 120, 130, and 140 may output the plurality of second reset signals.

FIG. 9 is a flowchart illustrating an example of outputting a plurality of second digital signals in a method of operating an image sensor according to example embodiments.

Referring to FIG. 9, in outputting the plurality of second digital signals (operation S400), the ramp signal may be outputted (operation S410).

Second photocharges may be transferred to the plurality of floating diffusions by turning on a plurality of second transfer transistors included in the plurality of second pixels (operation S420). The second photocharges may be generated in the plurality of second pixels.

A plurality of second analog pixel signals may be outputted based on the second photocharges transferred to the plurality of floating diffusions (operation S430).

The plurality of second pixel signals corresponding to a time point at which the ramp signal and the plurality of second analog pixel signals intersect may be outputted (operation S440).

The plurality of second digital signals may be obtained based on the plurality of second reset signals and the plurality of second pixel signals (operation S450).

FIGS. 10A and 10B are diagrams for describing an operation in FIG. 9.

Referring to FIG. 10A, second photocharges generated in the plurality of second pixels PX2 may be transferred to respective floating diffusions by turning on a plurality of second transfer transistors included in the plurality of second pixels PX2, and a plurality of second analog pixel signals AS_PX21, AS_PX22, AS_PX23, and AS_PX24 may be outputted to the analog-to-digital converter 200 based on the second photocharges transferred to the respective floating diffusions.

FIG. 10B illustrates only the first pixel PX1, the second pixel PX2, the third pixel PX3, and the third pixel PX3′ included in the pixel group 110 in the pixel array 100 in FIG. 10A, and represents an operation of generating the second analog pixel signal AS_PX21 and generating a second digital signal DS21 based on the second analog pixel signal AS_PX21.

Referring to FIG. 10B, the ramp signal S_RAMP that decreases or increases at a constant slope may be inputted to the comparator 210a. When the second transfer control signal TG2 is activated and the second transfer transistor TX2 is turned on, second photocharges generated in the second photodiode PD2 may be transferred to the first floating diffusion FD1. After the second transfer control signal TG2 is deactivated and the charge transfer operation is completed, the second analog pixel signal AS_PX21 may be outputted to the comparator 210a based on the second photocharges transferred to the first floating diffusion FD1.

For example, the comparator 210a may compare the ramp signal S_RAMP with the second analog pixel signal AS_PX21 and may output the comparison signal CS to the counter. The counter 220a may count the active interval (i.e., level transition time) of the comparison signal CS based on the count clock signal, and may output the second pixel signal S_PX21 to the calculator 230a. In other words, the counter 220a may output the second pixel signal S_PX21 corresponding to a time point at which the ramp signal S_RAMP and the second analog pixel signal AS_PX21 intersect to the calculator 230a.

For example, the calculator 230a may output the second digital signal DS21 based on the second reset signal (e.g., S_R21 in FIG. 8) and the second pixel signal S_PX21. For example, the calculator 230a may output a difference between the second reset signal S_R21 and the second pixel signal S_PX21 as the second digital signal DS21.

FIG. 11 is a flowchart illustrating an example of outputting a plurality of third digital signals in a method of operating an image sensor according to example embodiments.

Referring to FIG. 11, in outputting the plurality of third digital signals (operation S500), the ramp signal may be outputted (operation S510).

Third photocharges may be transferred to the plurality of floating diffusions by turning on a plurality of third transfer transistors included in the plurality of third pixels (operation S520). The third photocharges may be generated in the plurality of third pixels.

A plurality of third analog pixel signals may be outputted based on the second photocharges and the third photocharges transferred to the plurality of floating diffusions (operation S530).

The plurality of third pixel signals corresponding to a time point at which the ramp signal and the plurality of third analog pixel signals intersect may be outputted (operation S540).

The plurality of third digital signals may be obtained based on the plurality of second reset signals and the plurality of third pixel signals (operation S550).

FIGS. 12A and 12B are diagrams for describing an operation in FIG. 11.

Referring to FIG. 12A, third photocharges generated in the plurality of third pixels PX3 and PX3′ may be transferred to respective floating diffusions by turning on a plurality of transfer transistors included in the plurality of third pixels PX3 and PX3′, and a plurality of third analog pixel signals AS_PX31, AS_PX32, AS_PX33, and AS_PX34 may be outputted to the analog-to-digital converter 200 based on the third photocharges transferred to the respective floating diffusions.

FIG. 12B illustrates only the first pixel PX1, the second pixel PX2, the third pixel PX3, and the third pixel PX3′ included in the pixel group 110 in the pixel array 100 in FIG. 12A, and represents an operation of generating the third analog pixel signal AS_PX31 and generating a third digital signal DS31 based on the third analog pixel signal AS_PX31.

Referring to FIG. 12B, the ramp signal S_RAMP that decreases or increases at a constant slope may be inputted to the comparator 210a. When the third transfer control signal TG3 and the fourth transfer control signal TG4 are activated, and the third transfer transistor TX3 and the fourth transfer transistor TX4 are turned on, third photocharges generated in the third photodiode PD3 and the fourth photodiode PD4 may be transferred to the first floating diffusion FD1. After the third transfer control signal TG3 and the fourth transfer control signal TG4 are deactivated and the charge transfer operation is completed, the third analog pixel signal AS_PX31 may be outputted to the comparator 210a based on the second photocharges and the third photocharges transferred to the first floating diffusion FD1.

For example, the comparator 210a may compare the ramp signal S_RAMP with the third analog pixel signal AS_PX31 and may output the comparison signal CS to the counter 220a. The counter 220a may count the active interval (i.e., level transition time) of the comparison signal CS based on the count clock signal, and may output a third pixel signal S_PX31 to the calculator 230a. In other words, the counter 220a may output the third pixel signal S_PX31 corresponding to a time point at which the ramp signal S_RAMP and the third analog pixel signal AS_PX31 intersect to the calculator 230a.

For example, the calculator 230a may output the third digital signal DS31 based on the second reset signal (e.g., S_R21 in FIG. 8) and the third pixel signal S_PX31. For example, the calculator 230a may output a difference between the second reset signal S_R21 and the third pixel signal S_PX31 as the third digital signal DS31.

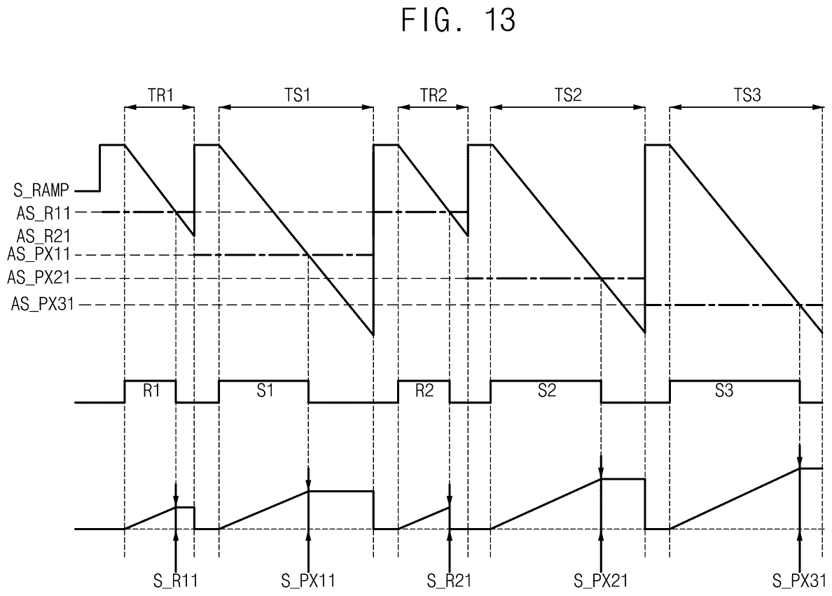

FIG. 13 is a timing diagram for describing operations in FIGS. 3, 5, 7, 9 and 11.

In FIG. 13, S_RAMP represents the ramp signal, AS_R11 represents the first analog reset signal (e.g., AS_R11 in FIG. 4), AS_R21 represents the second analog reset signal (e.g., AS_R21 in FIG. 8), AS_PX11 represents the first analog pixel signal (e.g., AS_PX11 in FIG. 6B), AS_PX21 represents the second analog pixel signal (e.g., AS_PX21 in FIG. 10B), AS_PX31 represents the third analog pixel signal (e.g., AS_PX31 in FIG. 12B), CS represents the comparison signal outputted from the comparator 210a, and CNT represents a count value of the counter 220a.

Referring to FIG. 13, in a first reset period TR1, the first reset signal S_R11 may be obtained based on a time point at which the ramp signal S_RAMP and the first analog reset signal AS_R11 intersect. For example, the comparison signal CS may have a logic high level from a start point of the first reset period TR1 to the time point at which the ramp signal S_RAMP and the first analog reset signal AS_R11 intersect. A length of an interval R1 in which the comparison signal CS has the logic high level in the first reset period TR1 may represent a voltage level of the first reset signal S_R11. For example, the count value CNT may be increased during the interval R1 to obtain the voltage level of the first reset signal S_R11.

In a first signal period TS1, the first pixel signal S_PX11 may be obtained based on a time point at which the ramp signal S_RAMP and the first analog pixel signal AS_PX11 intersect. For example, the comparison signal CS may have a logic high level from a start point of the first signal period TS1 to the time point at which the ramp signal S_RAMP and the first analog pixel signal AS_PX11 intersect. A length of an interval S1 in which the comparison signal CS has the logic high level in the first signal period TS1 may represent a voltage level of the first pixel signal S_PX11. For example, the count value CNT may be increased during the interval S1 to obtain the voltage level of the first pixel signal S_PX11.

In a second reset period TR2, the second reset signal S_R21 may be obtained based on a time point at which the ramp signal S_RAMP and the second analog reset signal AS_R21 intersect. For example, the comparison signal CS may have a logic high level from a start point of the second reset period TR2 to the time point at which the ramp signal S_RAMP and the second analog reset signal AS_R21 intersect. A length of an interval R2 in which the comparison signal CS has the logic high level in the second reset period TR2 may represent a voltage level of the second reset signal S_R21. For example, the count value CNT may be increased during the interval R2 to obtain the voltage level of the second reset signal S_R21.

In a second signal period TS2, the second pixel signal S_PX21 may be obtained based on a time point at which the ramp signal S_RAMP and the second analog pixel signal AS_PX21 intersect. For example, the comparison signal CS may have a logic high level from a start point of the second signal period TS2 to the time point at which the ramp signal S_RAMP and the second analog pixel signal AS_PX21 intersect. A length of an interval S2 in which the comparison signal CS has the logic high level in the second signal period TS2 may represent a voltage level of the second pixel signal S_PX21. For example, the count value CNT may be increased during the interval S2 to obtain the voltage level of the second pixel signal S_PX21.

In a third signal period TS3, the third pixel signal S_PX31 may be obtained based on a time point at which the ramp signal S_RAMP and the third analog pixel signal AS_PX31 intersect. For example, the comparison signal CS may have a logic high level from a start point of the third signal period TS3 to the time point at which the ramp signal S_RAMP and the third analog pixel signal AS_PX31 intersect. A length of an interval S3 in which the comparison signal CS has the logic high level in the third signal period TS3 may represent a voltage level of the third pixel signal S_PX31. For example, the count value CNT may be increased during the interval S3 to obtain the voltage level of the third pixel signal S_PX31.

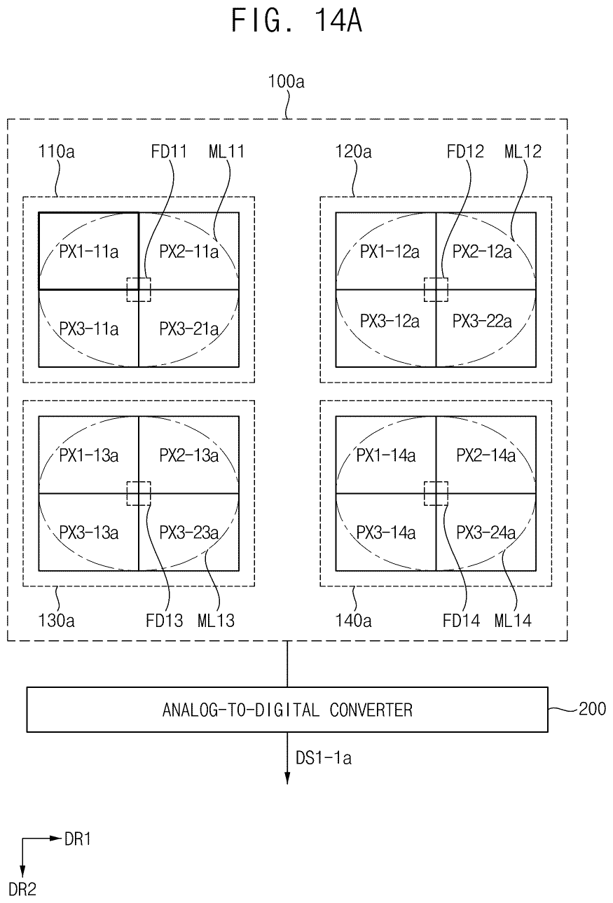

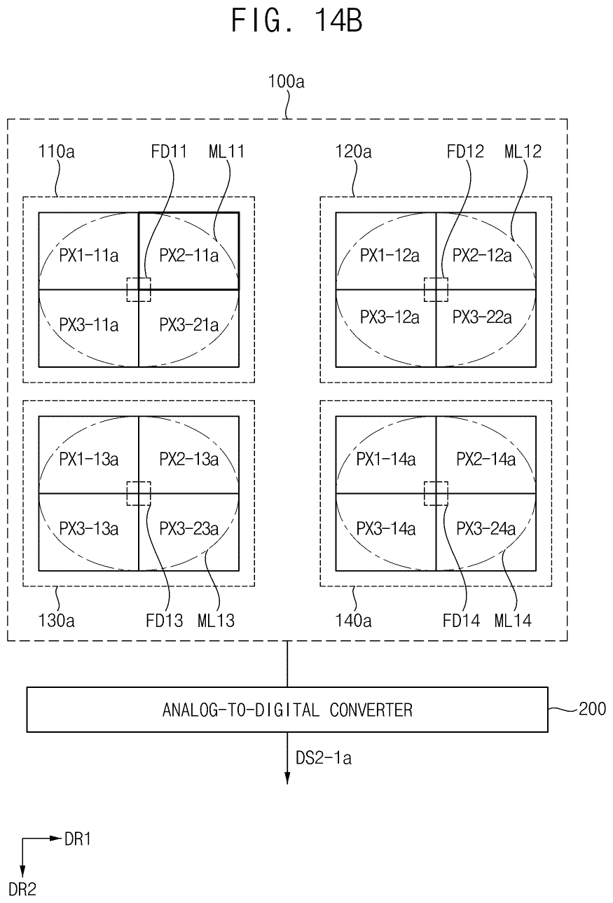

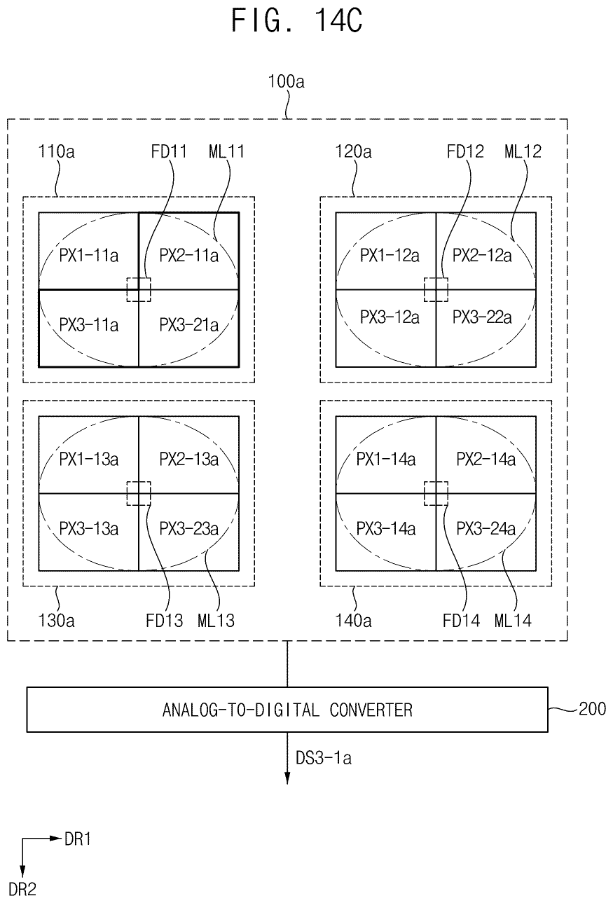

FIGS. 14A, 14B and 14C are diagrams illustrating examples of a pixel array and an analog-to-digital converter included in an image sensor according to example embodiments.

Referring to FIGS. 14A, 14B, and 14C, a pixel array 100a may include a first pixel group 110a, a second pixel group 120a, a third pixel group 130a, and a fourth pixel group 140a. The first pixel group 110a may include a first-first pixel PX1-11a, a second-first pixel PX2-11a, a third-first pixel PX3-11a, and a third-second pixel PX3-21a. The second pixel group 120a may include a first-first pixel PX1-12a, a second-first pixel PX2-12a, a third-first pixel PX3-12a, and a third-second pixel PX3-22a. The third pixel group 130a may include a first-first pixel PX1-13a, a second-first pixel PX2-13a, a third-first pixel PX3-13a, and a third-second pixel PX3-23a. The fourth pixel group 140a may include a first-first pixel PX1-14a, a second-first pixel PX2-14a, a third-first pixel PX3-14a, and a third-second pixel PX3-24a.

For example, the first-first pixel PX1-11a, the second-first pixel PX2-11a, the third-first pixel PX3-11a, and the third-second pixel PX3-21a may share a first floating diffusion FD11 and a first microlens ML11. The first-first pixel PX1-12a, the second-first pixel PX2-12a, the third-first pixel PX3-12a, and the third-second pixel PX3-22a may share a first floating diffusion FD12 and a first microlens ML12. The first-first pixel PX1-13a, the second-first pixel PX2-13a, the third-first pixel PX3-13a, and the third-second pixel PX3-23a may share a first floating diffusion FD13 and a first microlens ML13. The first-first pixel PX1-14a, the second-first pixel PX2-14a, the third-first pixel PX3-14a, and the third-second pixel PX3-24a may share a first floating diffusion FD14 and a first microlens ML14.

Although FIGS. 14A, 14B, and 14C illustrate a case where four pixel groups are arranged in a 2*2 pattern, example embodiments are not limited thereto, and the structure illustrated in FIGS. 14A, 14B, and 14C may be repeatedly arranged in the first direction DR1 and the second direction DR2.

Referring to FIG. 14A, by turning on a transfer transistor included in the first-first pixel PX1-11a, photocharges generated in the first-first pixel PX1-11a may be transferred to the first floating diffusion FD11, and a first-first digital signal DS1-1a may be outputted based on the photocharges transferred to the first floating diffusion FD11.

Referring to FIG. 14B, by turning on a transfer transistor included in the second-first pixel PX2-11a, photocharges generated in the second-first pixel PX2-11a may be transferred to the first floating diffusion FD11, and a second-first digital signal DS2-1a may be outputted based on the photocharges transferred to the first floating diffusion FD11.

Referring to FIG. 14C, by turning on transfer transistors included in the third-first pixel PX3-11a and the third-second pixel PX3-21a, photocharges generated in the third-first pixel PX3-11a and the third-second pixel PX3-21a may be transferred to the first floating diffusion FD11. A third-first digital signal DS3-1a may be outputted based on the photocharges transferred from the second-first pixel PX2-11a and the photocharges transferred from the third-first pixel PX3-11a and the third-second pixel PX3-21a.

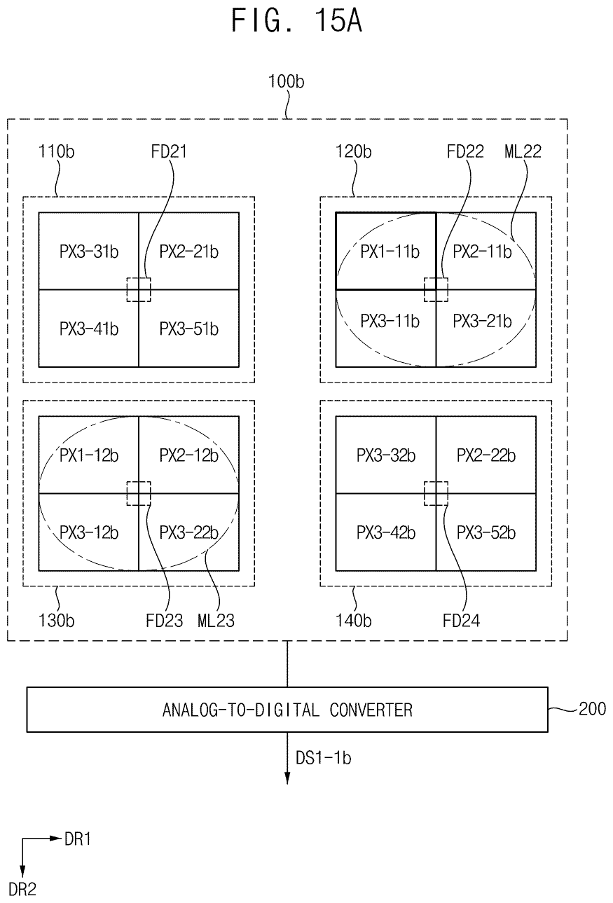

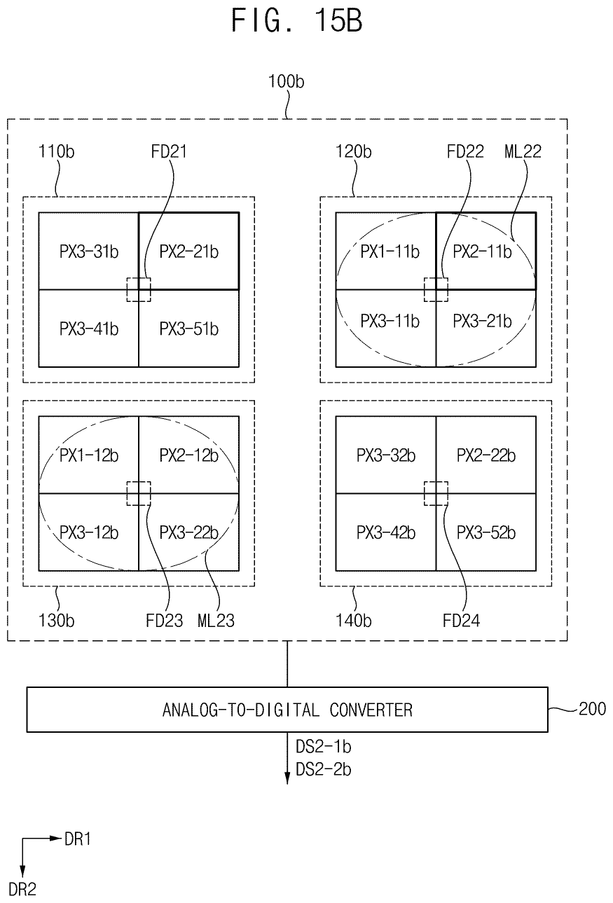

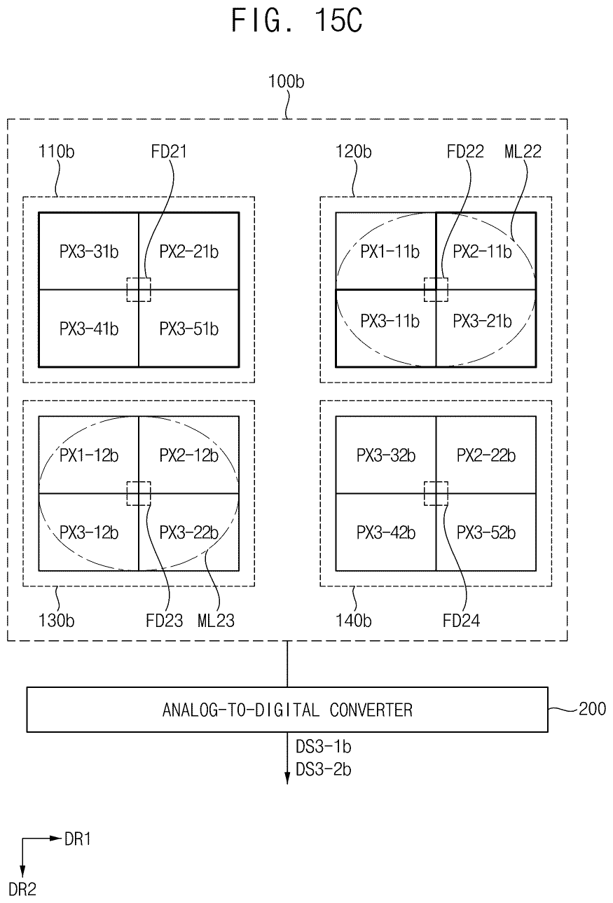

FIGS. 15A, 15B and 15C are diagrams illustrating examples of a pixel array and an analog-to-digital converter included in an image sensor according to example embodiments.

Referring to FIGS. 15A, 15B, and 15C, a pixel array 100b may include a first pixel group 110b, a second pixel group 120b, a third pixel group 130b, and a fourth pixel group 140b. The first pixel group 110b may include a third-third pixel PX3-31b, a second-second pixel PX2-21b, a third-fourth pixel PX3-41b, and a third-fifth pixel PX3-51b. The second pixel group 120b may include a first-first pixel PX1-11b, a second-first pixel PX2-11b, a third-first pixel PX3-11b, and a third-second pixel PX3-21b. The third pixel group 130b may include a first-first pixel PX1-12b, a second-first pixel PX2-12b, a third-first pixel PX3-12b, and a third-second pixel PX3-22b. The fourth pixel group 140b may include a third-third pixel PX3-32b, a second-second pixel PX2-22b, a third-fourth pixel PX3-42b, and a third-fifth pixel PX3-52b.

For example, the third-third pixel PX3-31b, the second-second pixel PX2-21b, the third-fourth pixel PX3-41b, and the third-fifth pixel PX3-51b may share a second floating diffusion FD21. The first-first pixel PX1-11b, the second-first pixel PX2-11b, the third-first pixel PX3-11b, and the third-second pixel PX3-21b may share a second floating diffusion FD22 and a second microlens ML22. The first-first pixel PX1-12b, the second-first pixel PX2-12b, the third-first pixel PX3-12b, and the third-second pixel PX3-22b may share a second floating diffusion FD23 and a second microlens ML23. The third-third pixel PX3-22b, the second-second pixel PX2-22b, the third-fourth pixel PX3-42b, and the third-fifth pixel PX3-52b may share a second floating diffusion FD24.

Although FIGS. 15A, 15B, and 15C illustrate a case where four pixel groups are arranged in a 2*2 pattern, example embodiments are not limited thereto, and the structures illustrated in FIGS. 15A, 15B, and 15C may be repeatedly arranged in the first direction DR1 and the second direction DR2.

Referring to FIG. 15A, by turning on a transfer transistor included in the first-first pixel PX1-11b, photocharges generated in the first-first pixel PX1-11b may be transferred to the second floating diffusion FD22, and a first-first digital signal DS1-1b may be outputted based on the photocharges transferred to the second floating diffusion FD22.

Referring to FIG. 15B, by turning on a transfer transistor included in the second-first pixel PX2-11b, photocharges generated in the second-first pixel PX2-11b may be transferred to the second floating diffusion FD22, and a second-first digital signal DS2-1b may be outputted based on the photocharges transferred to the second floating diffusion FD22.

Likewise, by turning on a transfer transistor included in the second-second pixel PX2-21b, photocharges generated in the second-second pixel PX2-21b may be transferred to the second floating diffusion FD21, and a second-second digital signal DS2-2b may be outputted based on the photocharges transferred to the second floating diffusion FD21.

Referring to FIG. 15C, by turning on transfer transistors included in the third-first pixel PX3-11b and the third-second pixel PX3-21b, photocharges generated in the third-first pixel PX3-11b and the third-second pixel PX3-21b may be transferred to the second floating diffusion FD22, and a third-first digital signal DS3-1b may be outputted based on the photocharges transferred from the second-first pixel PX2-11b, the third-first pixel PX3-11b, and the third-second pixel PX3-21b.

Likewise, by turning on transfer transistors included in the third-third pixel PX3-31b, the third-fourth pixel PX3-41b, and the third-fifth pixel PX3-51b, photocharges generated in the third-third pixel PX3-31b, the third-fourth pixel PX3-41b, and the third-fifth pixel PX3-51b may be transferred to the second floating diffusion FD21, and a third-second digital signal DS3-2b may be outputted based on the photocharges transferred from the second-second pixel PX2-21b, the third-third pixel PX3-31b, the third-fourth pixel PX3-41b, and the third-fifth pixel PX3-51b.

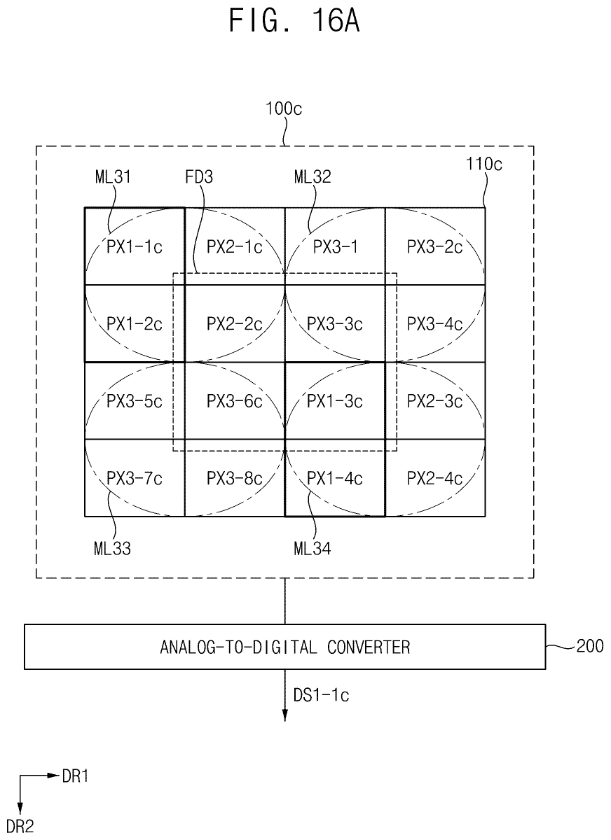

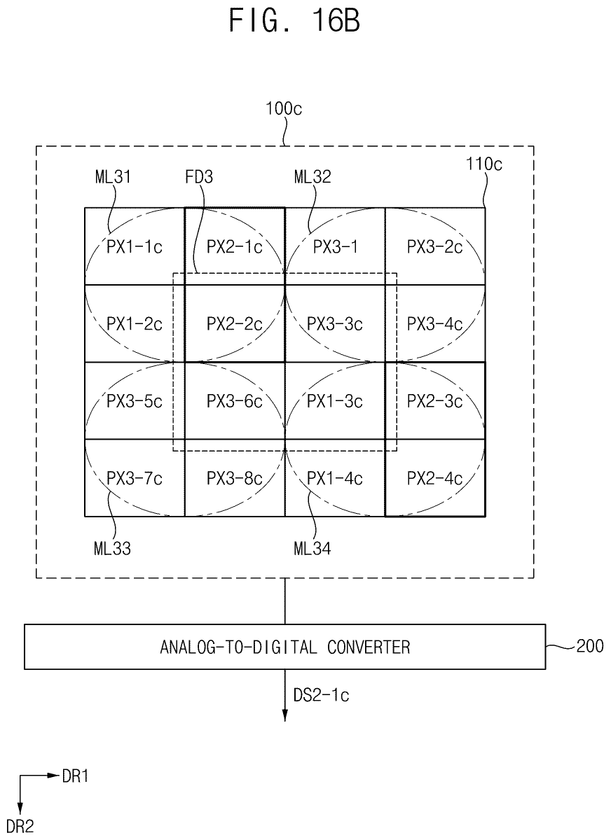

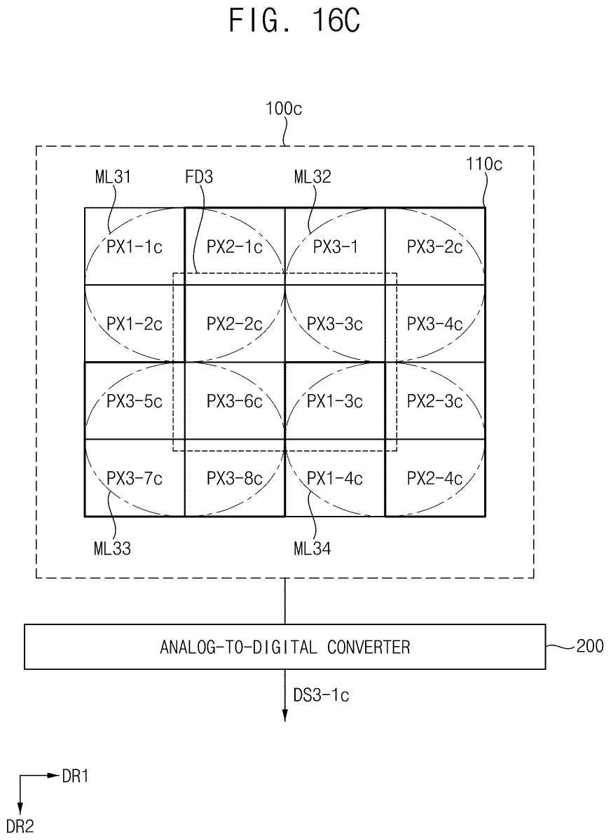

FIGS. 16A, 16B and 16C are diagrams illustrating examples of a pixel array and an analog-to-digital converter included in an image sensor according to example embodiments.

Referring to FIGS. 16A, 16B, and 16C, a pixel array 100c may include a first pixel group 110c. The first pixel group 110c may include a first-first pixel PX1-1c, a first-second pixel PX1-2c, a first-third pixel PX1-3c, a first-fourth pixel PX1-4c, a second-first pixel PX2-1c, a second-second pixel PX2-2c, a second-third pixel PX2-3c, a second-fourth pixel PX2-4c, a third-first pixel PX3-1c, a third-second pixel PX3-2c, a third-third pixel PX3-3c, a third-fourth pixel PX3-4c, a third-fifth pixel PX3-5c, a third-sixth pixel PX3-6c, a third-seventh pixel PX3-7c, and a third-eighth pixel PX3-8c.

For example, the first-first pixel PX1-1c, the first-second pixel PX1-2c, the first-third pixel PX1-3c, the first-fourth pixel PX1-4c, the second-first pixel PX2-1c, the second-second pixel PX2-2c, the second-third pixel PX2-3c, the second-fourth pixel PX2-4c, the third-first pixel PX3-1c, the third-second pixel PX3-2c, the third-third pixel PX3-3c, the third-fourth pixel PX3-4c, the third-fifth pixel PX3-5c, the third-sixth pixel PX3-6c, the third-seventh pixel PX3-7c, and the third-eighth pixel PX3-8c may share a third floating diffusion FD3.

For example, the first-first pixel PX1-1c, the first-second pixel PX1-2c, the second-first pixel PX2-1c, and the second-second pixel PX2-2c may share a third microlens ML31. The third-first pixel PX3-1c, the third-second pixel PX3-2c, the third-third pixel PX3-3c, and the third-fourth pixel PX3-4c may share a third microlens ML32. The third-fifth pixel PX3-5c, the third-sixth pixel PX3-6c, the third-seventh pixel PX3-7c, and the third-eighth pixel PX3-8c may share a third microlens ML33. The first-third pixel PX1-3c, the first-fourth pixel PX1-4c, the second-third pixel PX2-3c, and the second-fourth pixel PX2-4c may share a third microlens ML34.

Although FIGS. 16A, 16B, and 16C illustrate a case where one pixel group is arranged in a 4*4 pattern, example embodiments are not limited thereto, and the structure illustrated in FIGS. 16A, 16B, and 16C may be repeatedly arranged in the first direction DR1 and the second direction DR2.

Referring to FIG. 16A, by turning on transfer transistors included in the first-first pixel PX1-1c, the first-second pixel PX1-2c, the first-third pixel PX1-3c, and the first-fourth pixel PX1-4c, photocharges generated in the first-first pixel PX1-1c, the first-second pixel PX1-2c, the first-third pixel PX1-3c, and the first-fourth pixel PX1-4c may be transferred to the third floating diffusion FD3, and a first-first digital signal DS1-1c may be outputted based on the photocharges transferred to the third floating diffusion FD3.

Referring to FIG. 16B, by turning on transfer transistors included in the second-first pixel PX2-1c, the second-second pixel PX2-2c, the second-third pixel PX2-3c, and the second-fourth pixel PX2-4c, photocharges generated in the second-first pixel PX2-1c, the second-second pixel PX2-2c, the second-third pixel PX2-3c, and the second-fourth pixel PX2-4c may be transferred to the third floating diffusion FD3, and a second-first digital signal DS2-1c may be outputted based on the photocharges transferred to the third floating diffusion FD3.

Referring to FIG. 16C, by turning on transfer transistors included in the third-first pixel PX3-1c, the third-second pixel PX3-2c, the third-third pixel PX3-3c, the third-fourth pixel PX3-4c, the third-fifth pixel PX3-5c, the third-sixth pixel PX3-6c, the third-seventh pixel PX3-7c, and the third-eighth pixel PX3-8c, photocharges generated in the third-first pixel PX3-1c, the third-second pixel PX3-2c, the third-third pixel PX3-3c, the third-fourth pixel PX3-4c, the third-fifth pixel PX3-5c, the third-sixth pixel PX3-6c, the third-seventh pixel PX3-7c, and the third-eighth pixel PX3-8c may be transferred to the third floating diffusion FD3, and a third-first digital signal DS3-1c may be outputted based on the photocharges transferred from the second-first pixel PX2-1c, the second-second pixel PX2-2c, the second-third pixel PX2-3c, the second-fourth pixel PX2-4c, and from the third-first pixel PX3-1c, the third-second pixel PX3-2c, the third-third pixel PX3-3c, the third-fourth pixel PX3-4c, the third-fifth pixel PX3-5c, the third-sixth pixel PX3-6c, the third-seventh pixel PX3-7c, and the third-eighth pixel PX3-8c.

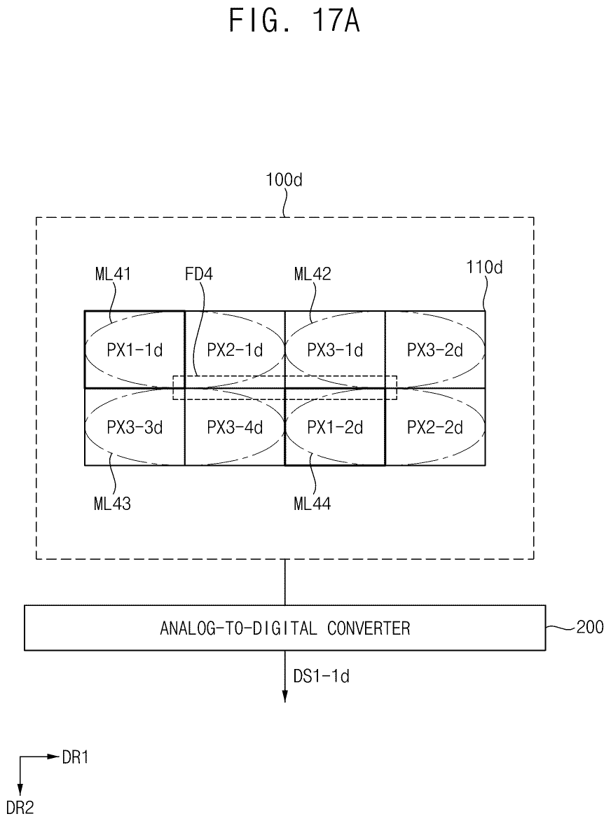

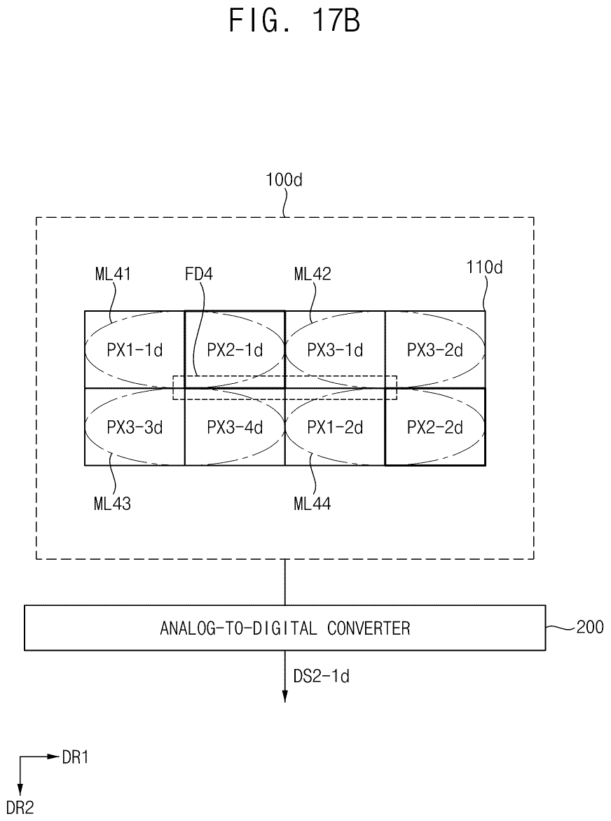

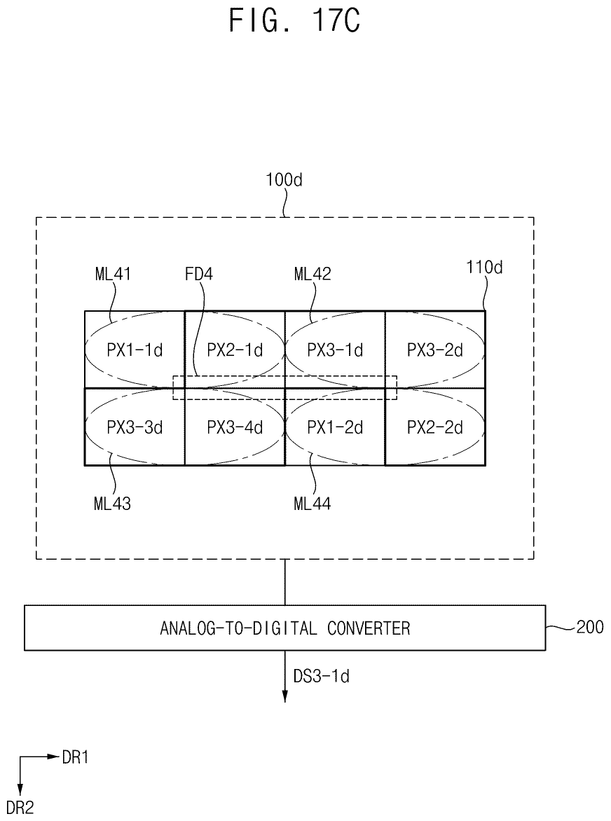

FIGS. 17A, 17B and 17C are diagrams illustrating examples of a pixel array and an analog-to-digital converter included in an image sensor according to example embodiments.

Referring to FIGS. 17A, 17B, and 17C, a pixel array 100d may include a first pixel group 110d. The first pixel group 110d may include a first-first pixel PX1-1d, a first-second pixel PX1-2d, a second-first pixel PX2-1d, a second-second pixel PX2-2d, a third-first pixel PX3-1d, a third-second pixel PX3-2d, a third-third pixel PX3-3d, and a third-fourth pixel PX3-4d.

For example, the first-first pixel PX1-1d, the first-second pixel PX1-2d, the second-first pixel PX2-1d, the second-second pixel PX2-2d, the third-first pixel PX3-1d, the third-second pixel PX3-2d, the third-third pixel PX3-3d, and the third-fourth pixel PX3-4d may share a fourth floating diffusion FD4.

For example, the first-first pixel PX1-1d and the second-first pixel PX2-1d may share a fourth microlens ML41, the third-first pixel PX3-1d and the third-second pixel PX3-2d may share a fourth microlens ML42, the third-third pixel PX3-3d and the third-fourth pixel PX3-4d may share a fourth microlens ML43, and the first-second pixel PX1-2d and the second-second pixel PX2-2d may share a fourth microlens ML44.

Although FIGS. 17A, 17B, and 17C illustrate a case where one pixel group is arranged in a 4*2 pattern, example embodiments are not limited thereto, and the structure illustrated in FIGS. 17A, 17B, and 17C may be repeatedly arranged in the first direction DR1 and the second direction DR2.

Referring to FIG. 17A, by turning on transfer transistors included in the first-first pixel PX1-1d and the first-second pixel PX1-2d, photocharges generated in the first-first pixel PX1-1d and the first-second pixel PX1-2d may be transferred to the fourth floating diffusion FD4, and a first-first digital signal DS1-1d may be outputted based on the photocharges transferred to the fourth floating diffusion FD4.

Referring to FIG. 17B, by turning on transfer transistors included in the second-first pixel PX2-1d and the second-second pixel PX2-2d, photocharges generated in the second-first pixel PX2-1d and the second-second pixel PX2-2d may be transferred to the fourth floating diffusion FD4, and a second-first digital signal DS2-1d may be outputted based on the photocharges transferred to the fourth floating diffusion FD4.

Referring to FIG. 17C, by turning on transfer transistors included in the third-first pixel PX3-1d, the third-second pixel PX3-2d, the third-third pixel PX3-3d, and the third-fourth pixel PX3-4d, photocharges generated in the third-first pixel PX3-1d, the third-second pixel PX3-2d, the third-third pixel PX3-3d, and the third-fourth pixel PX3-4d may be transferred to the fourth floating diffusion FD4, and a third-first digital signal DS3-1d may be outputted based on the photocharges transferred from the second-first pixel PX2-1d, the second-second pixel PX2-2d, and from the third-first pixel PX3-1d, the third-second pixel PX3-2d, the third-third pixel PX3-3d, and the third-fourth pixel PX3-4d.

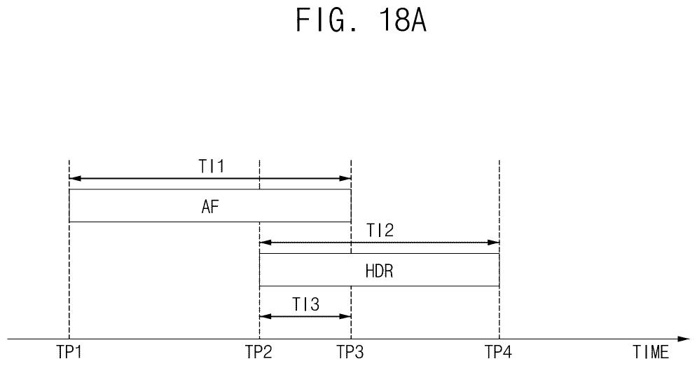

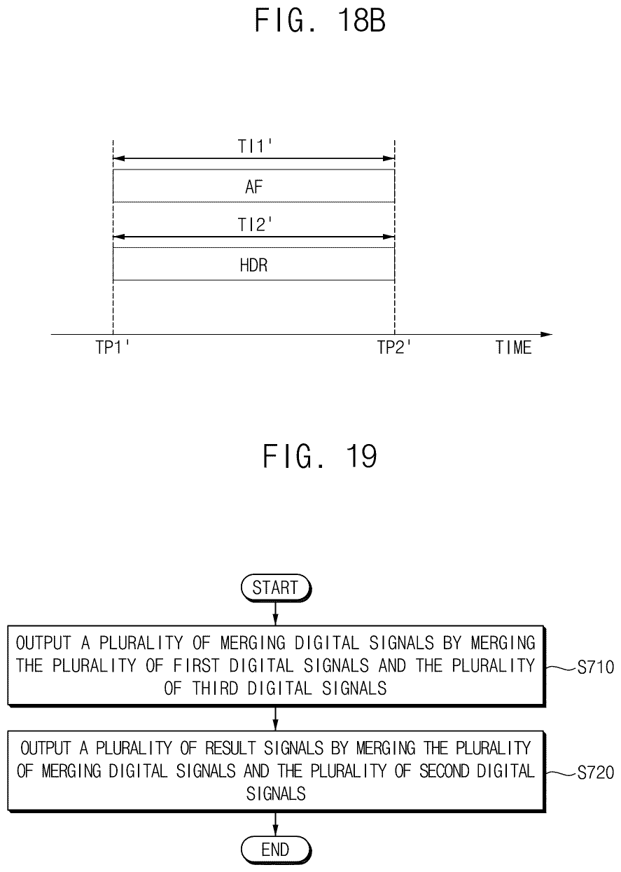

FIGS. 18A and 18B are diagrams for describing examples of performing an AF operation and performing an HDR merging operation in a method of operating an image sensor according to example embodiments.

Referring to FIG. 18A, a first time interval TI1 may be an interval between a first time point TP1 and a second time point TP2, a second time interval TI2 may be an interval between the second time point TP2 and a fourth time point TP4, and a third time interval TI3 may be an interval between the second time point TP2 and a third time point TP3.

For example, at least a portion of the first time interval TI1 in which the AF operation is performed and at least a portion of the second time interval TI2 in which the HDR merging operation is performed may overlap. For example, at least a portion of the first time interval TI1 in which the AF circuit (e.g., 300 in FIG. 2) performs the AF operation and at least a portion of the second time interval TI2 in which the HDR circuit (e.g., 400 in FIG. 2) performs the HDR merging operation may overlap by the third time interval TI3. In other words, the AF operation and the HDR merging operation may be performed simultaneously.

However, example embodiments are not limited thereto, and a first time interval TI1 in which the AF operation is performed and the second time interval TI2 in which the HDR merging operation is performed may not overlap.

Referring to FIG. 18B, a first time interval TI1′ may be an interval between a first time point TP1′ and a second time point TP2′, and a second time interval TI2′ may also be an interval between the first time point TP1′ and the second time point TP2′.

For example, the first time interval TI1′ in which the AF operation is performed and the second time interval TI2′ in which the HDR merging operation is performed may be the same time interval. In other words, the AF operation and the HDR merging operation may start at the same time point and end at the same time point.

FIG. 19 is a flowchart illustrating an example of performing an HDR merging operation in a method of operating an image sensor according to example embodiments.

Referring to FIG. 19, in performing the HDR merging operation (operation S700), a plurality of merging digital signals may be outputted by merging the plurality of first digital signals and the plurality of third digital signals (operation S710).

A plurality of result signals may be outputted by merging the plurality of merging digital signals and the plurality of second digital signals (operation S720).

Operations S710 and S720 may be performed by the first merging circuit (e.g. 410a in FIG. 20) and the second merging circuit (e.g. 420a in FIG. 20), respectively.

FIG. 20 is a block diagram illustrating an example of an HDR circuit included in an image sensor according to example embodiments.

Referring to FIG. 20, an HDR circuit 400a may include a first merging circuit 410a and a second merging circuit 420a. The HDR circuit 400a is substantially the same as the HDR circuit 400 in FIG. 2. Hereinafter, the descriptions repeated with or overlapping with descriptions of FIG. 2 will be omitted in the interest of brevity.

The first merging circuit 410a may output a plurality of merging digital signals MDS to the second merging circuit 420a by merging the plurality of first digital signals DS1 and the plurality of third digital signals DS3.

The second merging circuit 420a may output a plurality of result signals RS by merging the plurality of merging digital signals MDS and the plurality of second digital signals DS2.

In some example embodiments, the plurality of result signals RS may be provided to an external processor (e.g., an image signal processor (ISP) and/or an application processor (AP)). The external processor may perform an image processing operation based on the plurality of result signals RS, and may further perform an image correction operation.

For example, the HDR merging operation may be performed according to [Equation 1]

$$RS = α * MDS + ( 1 - α ) * Norm ( PhaseCorrection ( DS 2 , MDS ) ) \qquad [ Equation 1 ]$$

In the [Equation 1], PhaseCorrection(DS2, MDS) refers to correcting a phase difference that may exist between the plurality of second digital signals DS2 and the plurality of merging digital signals MDS. To correct the phase difference, techniques such as normalized cross correlation (NCC) or pattern matching may be used, and various interpolation methods including B-spline, cubic spline, Lagrange interpolation, Hermite interpolation, and Catmull-Rom interpolation may be used.

In the [Equation 1], Norm( ) functions to match the sensitivity ratio between two signals having different sensitivities. In the [Equation 1], α is a value used for blending the two images and may be determined according to the magnitudes of the respective signals.

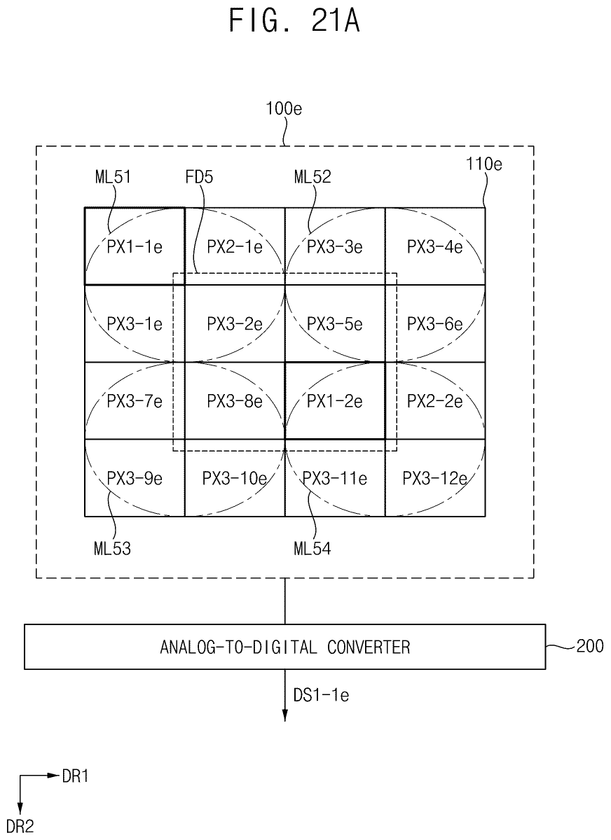

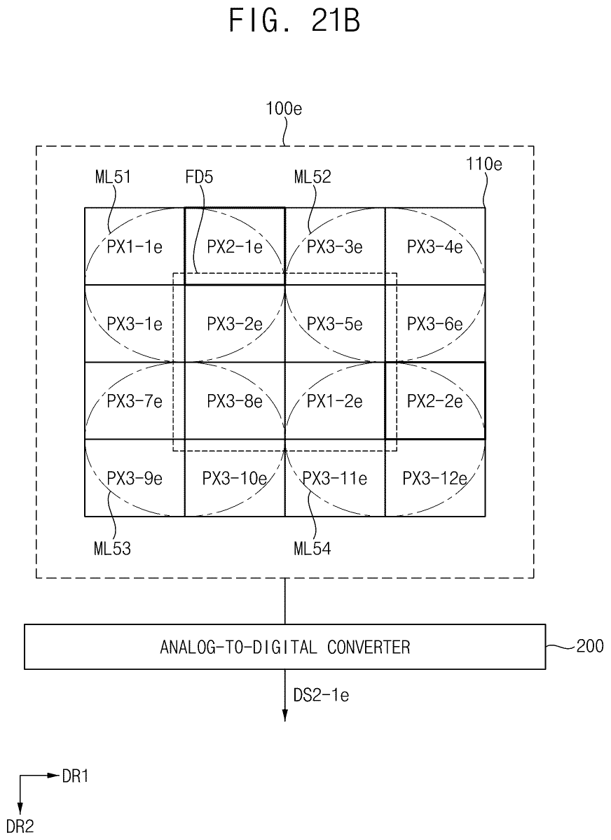

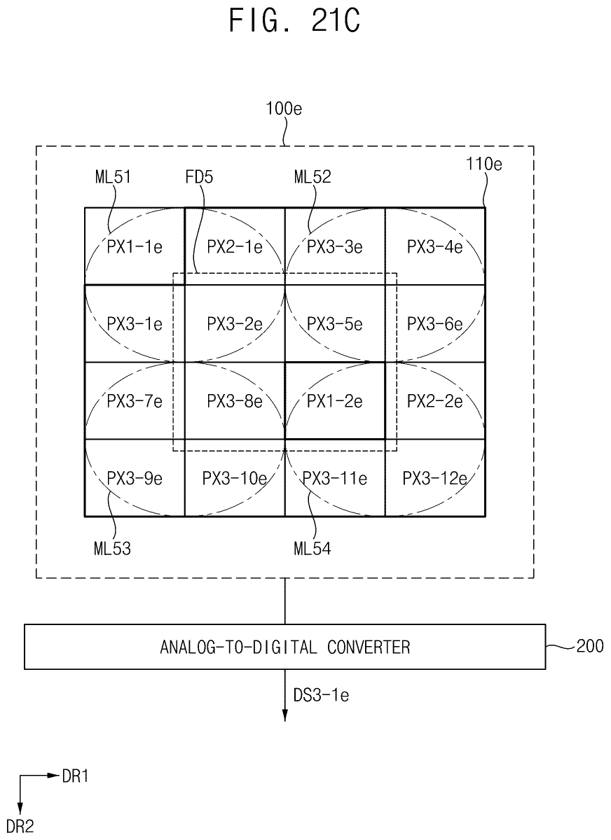

FIGS. 21A, 21B and 21C are diagrams illustrating examples of a pixel array and an analog-to-digital converter included in an image sensor according to example embodiments.

Referring to FIGS. 21A, 21B, and 21C, a pixel array 100e may include a first pixel group 110e. The first pixel group 110e may include a first-first pixel PX1-1e, a first-second pixel PX1-2e, a second-first pixel PX2-1e, a second-second pixel PX2-2e, a third-first pixel PX3-1e, a third-second pixel PX3-2e, a third-third pixel PX3-3e, a third-fourth pixel PX3-4e, a third-fifth pixel PX3-5e, a third-sixth pixel PX3-6e, a third-seventh pixel PX3-7e, a third-eighth pixel PX3-8e, a third-ninth pixel PX3-9e, a third-tenth pixel PX3-10e, a third-eleventh pixel PX3-11e, and a third-twelfth pixel PX3-12e.

For example, the first-first pixel PX1-1e, the first-second pixel PX1-2e, the second-first pixel PX2-1e, the second-second pixel PX2-2e, the third-first pixel PX3-1e, the third-second pixel PX3-2e, the third-third pixel PX3-3e, the third-fourth pixel PX3-4e, the third-fifth pixel PX3-5e, the third-sixth pixel PX3-6e, the third-seventh pixel PX3-7e, the third-eighth pixel PX3-8e, the third-ninth pixel PX3-9e, the third-tenth pixel PX3-10e, the third-eleventh pixel PX3-11e, and the third-twelfth pixel PX3-12e may share a fifth floating diffusion FD5.

For example, the first-first pixel PX1-1e, the second-first pixel PX2-1e, the third-first pixel PX3-1e, and the third-second pixel PX3-2e may share a fifth microlens ML51, the third-third pixel PX3-3e, the third-fourth pixel PX3-4e, the third-fifth pixel PX3-5e, and the third-sixth pixel PX3-6e may share a fifth microlens ML52, the third-seventh pixel PX3-7e, the third-eighth pixel PX3-8e, the third-ninth pixel PX3-9e, and the third-tenth pixel PX3-10e may share a fifth microlens ML53, and the first-second pixel PX1-2e, the second-second pixel PX2-2e, the third-eleventh pixel PX3-11e, and the third-twelfth pixel PX3-12e may share a fifth microlens ML54.

Although FIGS. 21A, 21B, and 21C illustrate a case where one pixel group is arranged in a 4*4 pattern, example embodiments are not limited thereto, and the structure illustrated in FIGS. 21A, 21B, and 21C may be repeatedly arranged in the first direction DR1 and the second direction DR2.

Referring to FIG. 21A, by turning on transfer transistors included in the first-first pixel PX1-1e and the first-second pixel PX1-2e, photocharges generated in the first-first pixel PX1-1e and the first-second pixel PX1-2e may be transferred to the fifth floating diffusion FD5, and a first-first digital signal DS1-1e may be outputted based on the photocharges transferred to the fifth floating diffusion FD5.

Referring to FIG. 21B, by turning on transfer transistors included in the second-first pixel PX2-1e and the second-second pixel PX2-2e, photocharges generated in the second-first pixel PX2-1e and the second-second pixel PX2-2e may be transferred to the fifth floating diffusion FD5, and a second-first digital signal DS2-1e may be outputted based on the photocharges transferred to the fifth floating diffusion FD5.

Referring to FIG. 21C, by turning on transfer transistors included in the third-first pixel PX3-1e, the third-second pixel PX3-2e, the third-third pixel PX3-3e, the third-fourth pixel PX3-4e, the third-fifth pixel PX3-5e, the third-sixth pixel PX3-6e, the third-seventh pixel PX3-7e, the third-eighth pixel PX3-8e, the third-ninth pixel PX3-9e, the third-tenth pixel PX3-10e, the third-eleventh pixel PX3-11e, and the third-twelfth pixel PX3-12e, photocharges generated in the third-first pixel PX3-1e, the third-second pixel PX3-2e, the third-third pixel PX3-3e, the third-fourth pixel PX3-4e, the third-fifth pixel PX3-5e, the third-sixth pixel PX3-6e, the third-seventh pixel PX3-7e, the third-eighth pixel PX3-8e, the third-ninth pixel PX3-9e, the third-tenth pixel PX3-10e, the third-eleventh pixel PX3-11e, and the third-twelfth pixel PX3-12e may be transferred to the fifth floating diffusion FD5, and a third-first digital signal DS3-1e may be outputted based on the photocharges transferred from the second-first pixel PX2-1e, the second-second pixel PX2-2e, and the photocharges transferred from the third-first pixel PX3-1e, the third-second pixel PX3-2e, the third-third pixel PX3-3e, the third-fourth pixel PX3-4e, the third-fifth pixel PX3-5e, the third-sixth pixel PX3-6e, the third-seventh pixel PX3-7e, the third-eighth pixel PX3-8e, the third-ninth pixel PX3-9e, the third-tenth pixel PX3-10e, the third-eleventh pixel PX3-11e, and the third-twelfth pixel PX3-12e.

For example, the HDR circuit (e.g., 400a in FIG. 20) may perform the HDR merging operation based on the first-first digital signal DS1-1e, the second-first digital signal DS2-1e, and the third-first digital signal DS3-1e. The HDR merging may be performed between the second-first and second-second pixels PX2-1e and PX2-2e and all of the pixels included in the first pixel group 100e. Since the number of the second-first and second-second pixels PX2-1e and PX2-2e is two and the number of pixels included in the first pixel group 100e is sixteen, FIGS. 21A, 21B, and 21C illustrate a 1:8 HDR merging operation. However, example embodiments are not limited thereto, and the HDR merging operation with various ratios may be performed.

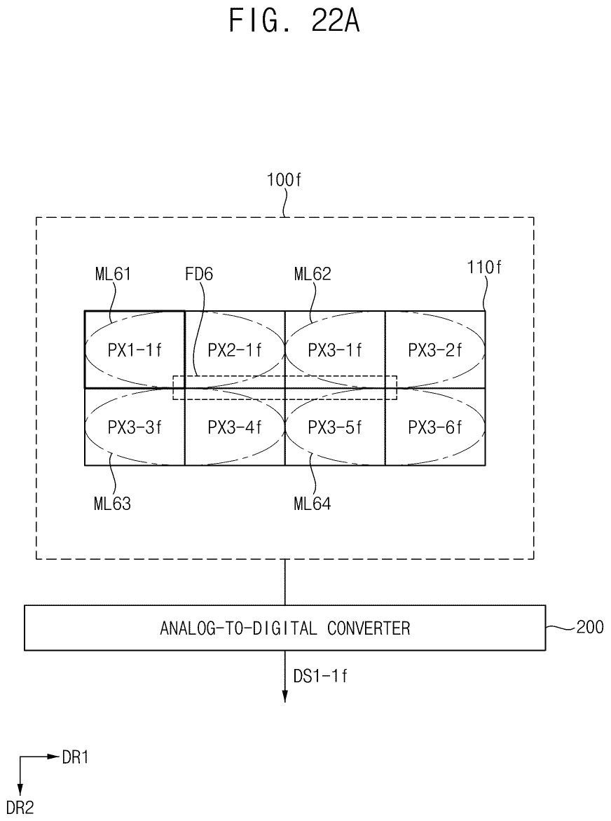

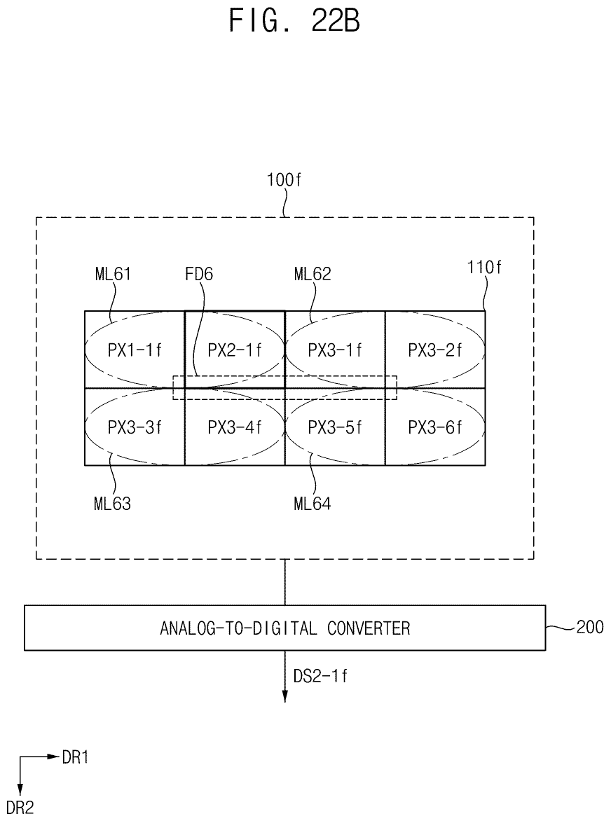

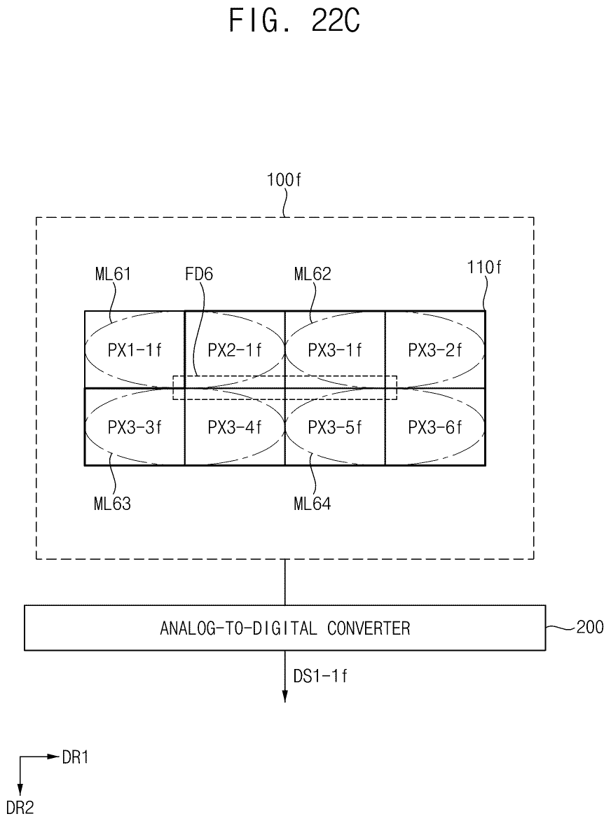

FIGS. 22A, 22B and 22C are diagrams illustrating examples of a pixel array and an analog-to-digital converter included in an image sensor according to example embodiments.

Referring to FIGS. 22A, 22B, and 22C, a pixel array 100f may include a first pixel group 110f. The first pixel group 110f may include a first-first pixel PX1-1f, a second-first pixel PX2-1f, a third-first pixel PX3-1f, a third-second pixel PX3-2f, a third-third pixel PX3-3f, a third-fourth pixel PX3-4f, a third-fifth pixel PX3-5f, and a third-sixth pixel PX3-6f.

For example, the first-first pixel PX1-1f, the second-first pixel PX2-1f, the third-first pixel PX3-1f, the third-second pixel PX3-2f, the third-third pixel PX3-3f, the third-fourth pixel PX3-4f, the third-fifth pixel PX3-5f, and the third-sixth pixel PX3-6f may share a sixth floating diffusion FD6.

For example, the first-first pixel PX1-1f and the second-first pixel PX2-1f may share a sixth microlens ML61, the third-first pixel PX3-1f and the third-second pixel PX3-2f may share a sixth microlens ML62, the third-third pixel PX3-3f and the third-fourth pixel PX3-4f may share a sixth microlens ML63, and the third-fifth pixel PX3-5f and the third-sixth pixel PX3-6f may share a sixth microlens ML64.

Although FIGS. 22A, 22B, and 22C illustrate a case where one pixel group is arranged in a 4*2 pattern, example embodiments are not limited thereto, and the structure illustrated in FIGS. 22A, 22B, and 22C may be repeatedly arranged in the first direction DR1 and the second direction DR2.

Referring to FIG. 22A, by turning on a transfer transistor included in the first-first pixel PX1-1f, photocharges generated in the first-first pixel PX1-1f may be transferred to the sixth floating diffusion FD6, and a first-first digital signal DS1-1f may be outputted based on the photocharges transferred to the sixth floating diffusion FD6.

Referring to FIG. 22B, by turning on a transfer transistor included in the second-first pixel PX2-1f, photocharges generated in the second-first pixel PX2-1f may be transferred to the sixth floating diffusion FD6, and a second-first digital signal DS2-1f may be outputted based on the photocharges transferred to the sixth floating diffusion FD6.

Referring to FIG. 22C, by turning on transfer transistors included in the third-first pixel PX3-1f, the third-second pixel PX3-2f, the third-third pixel PX3-3f, the third-fourth pixel PX3-4f, the third-fifth pixel PX3-5f, and the third-sixth pixel PX3-6f, photocharges generated in the third-first pixel PX3-1f, the third-second pixel PX3-2f, the third-third pixel PX3-3f, the third-fourth pixel PX3-4f, the third-fifth pixel PX3-5f, and the third-sixth pixel PX3-6f may be transferred to the sixth floating diffusion FD6, and a third-first digital signal DS3-1f may be outputted based on the photocharges transferred from the second-first pixel PX2-1f and from the third-first pixel PX3-1f, the third-second pixel PX3-2f, the third-third pixel PX3-3f, the third-fourth pixel PX3-4f, the third-fifth pixel PX3-5f, and the third-sixth pixel PX3-6f.

For example, the HDR circuit (e.g., 400a in FIG. 20) may perform the HDR merging operation based on the first-first digital signal DS1-1f, the second-first digital signal DS2-1f, and the third-first digital signal DS3-1f. The HDR merging operation may be performed between the second-first pixel PX2-1f and all of the pixels included in the first pixel group 100f. Since the number of pixels included in the first pixel group 100f is eight, FIGS. 22A, 22B, and 22C illustrate a 1:8 HDR merging operation. However, example embodiments are not limited thereto, and the HDR merging operation with various ratios may be performed.

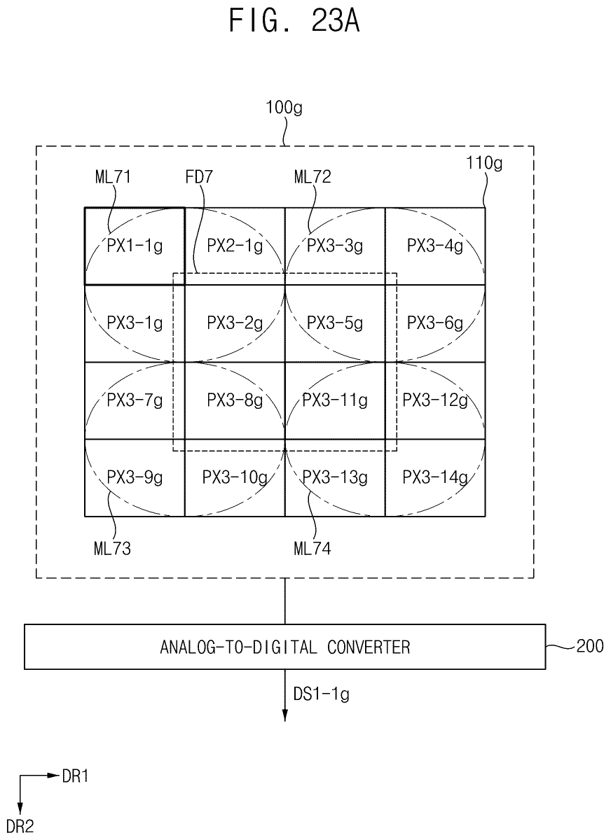

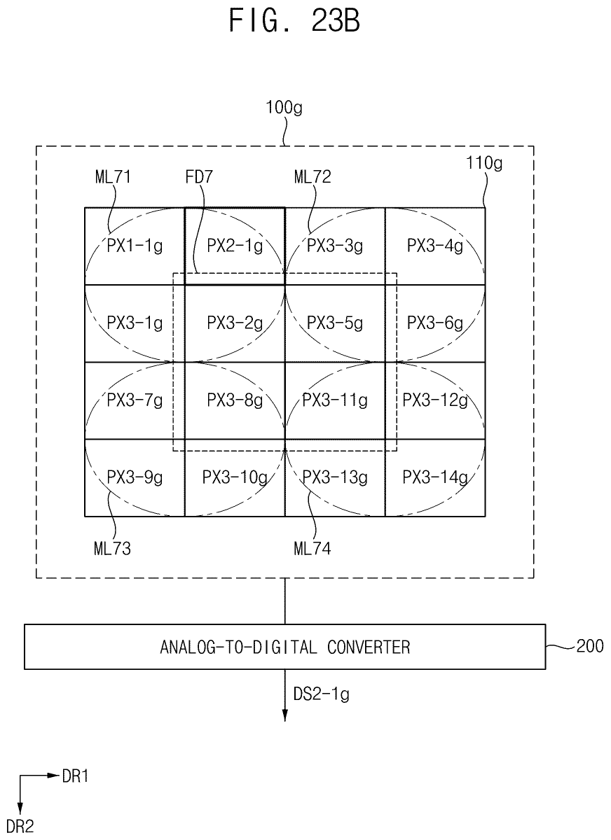

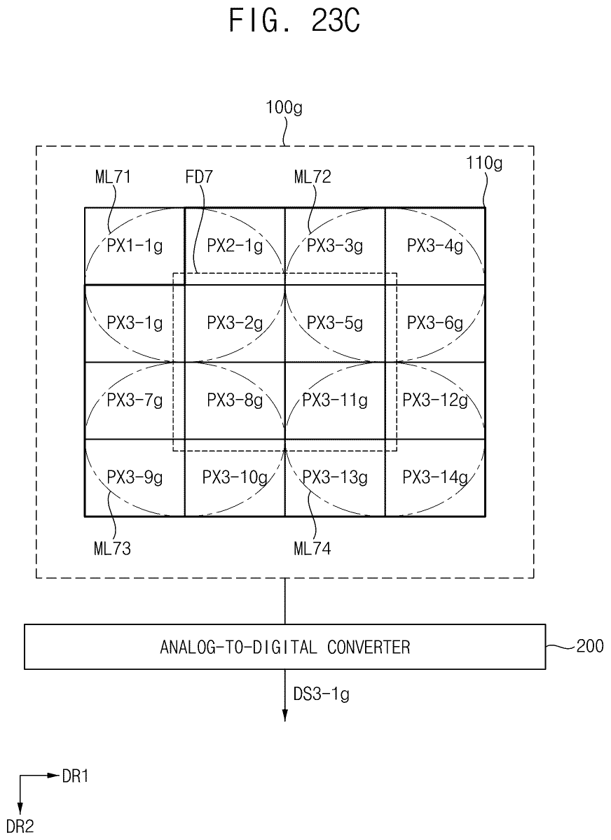

FIGS. 23A, 23B and 23C are diagrams illustrating examples of a pixel array and an analog-to-digital converter included in an image sensor according to example embodiments.

Referring to FIGS. 23A, 23B, and 23C, a pixel array 100g may include a first pixel group 110g. The first pixel group 110g may include a first-first pixel PX1-1g, a second-first pixel PX2-1g, a third-first pixel PX3-1g, a third-second pixel PX3-2g, a third-third pixel PX3-3g, a third-fourth pixel PX3-4g, a third-fifth pixel PX3-5g, a third-sixth pixel PX3-6g, a third-seventh pixel PX3-7g, a third-eighth pixel PX3-8g, a third-ninth pixel PX3-9g, a third-tenth pixel PX3-10g, a third-eleventh pixel PX3-11g, a third-twelfth pixel PX3-12g, a third-thirteenth pixel PX3-13g, and a third-fourteenth pixel PX3-14g.

For example, the first-first pixel PX1-1g, the second-first pixel PX2-1g, the third-first pixel PX3-1g, the third-second pixel PX3-2g, the third-third pixel PX3-3g, the third-fourth pixel PX3-4g, the third-fifth pixel PX3-5g, the third-sixth pixel PX3-6g, the third-seventh pixel PX3-7g, the third-eighth pixel PX3-8g, the third-ninth pixel PX3-9g, the third-tenth pixel PX3-10g, the third-eleventh pixel PX3-11g, the third-twelfth pixel PX3-12g, the third-thirteenth pixel PX3-13g, and the third-fourteenth pixel PX3-14g may share a seventh floating diffusion FD7.

For example, the first-first pixel PX1-1g, the second-first pixel PX2-1g, the third-first pixel PX3-1g, and the third-second pixel PX3-2g may share a seventh microlens ML71, the third-third pixel PX3-3g, the third-fourth pixel PX3-4g, the third-fifth pixel PX3-5g, and the third-sixth pixel PX3-6g may share a seventh microlens ML72, the third-seventh pixel PX3-7g, the third-eighth pixel PX3-8g, the third-ninth pixel PX3-9g, and the third-tenth pixel PX3-10g may share a seventh microlens ML73, and the third-eleventh pixel PX3-11g, the third-twelfth pixel PX3-12g, the third-thirteenth pixel PX3-13g, and the third-fourteenth pixel PX3-14g may share a seventh microlens ML74.

Although FIGS. 23A, 23B, and 23C illustrate a case where one pixel group is arranged in a 4*4 pattern, example embodiments are not limited thereto, and the structure illustrated in FIGS. 23A, 23B, and 23C may be repeatedly arranged in the first direction DR1 and the second direction DR2.

Referring to FIG. 23A, by turning on a transfer transistor included in the first-first pixel PX1-1g, photocharges generated in the first-first pixel PX1-1g may be transferred to the seventh floating diffusion FD7, and a first-first digital signal DS1-1g may be outputted based on the photocharges transferred to the seventh floating diffusion FD7.

Referring to FIG. 23B, by turning on a transfer transistor included in the second-first pixel PX2-1g, photocharges generated in the second-first pixel PX2-1g may be transferred to the seventh floating diffusion FD7, and a second-first digital signal DS2-1g may be outputted based on the photocharges transferred to the seventh floating diffusion FD7.

Referring to FIG. 23C, by turning on transfer transistors included in the third-first pixel PX3-1g, the third-second pixel PX3-2g, the third-third pixel PX3-3g, the third-fourth pixel PX3-4g, the third-fifth pixel PX3-5g, the third-sixth pixel PX3-6g, the third-seventh pixel PX3-7g, the third-eighth pixel PX3-8g, the third-ninth pixel PX3-9g, the third-tenth pixel PX3-10g, the third-eleventh pixel PX3-11g, the third-twelfth pixel PX3-12g, the third-thirteenth pixel PX3-13g, and the third-fourteenth pixel PX3-14g, photocharges generated in the third-first pixel PX3-1g, the third-second pixel PX3-2g, the third-third pixel PX3-3g, the third-fourth pixel PX3-4g, the third-fifth pixel PX3-5g, the third-sixth pixel PX3-6g, the third-seventh pixel PX3-7g, the third-eighth pixel PX3-8g, the third-ninth pixel PX3-9g, the third-tenth pixel PX3-10g, the third-eleventh pixel PX3-11g, the third-twelfth pixel PX3-12g, the third-thirteenth pixel PX3-13g, and the third-fourteenth pixel PX3-14g may be transferred to the seventh floating diffusion FD7, and a third-first digital signal DS3-1g may be outputted based on the photocharges transferred from the second-first pixel PX2-1g and the photocharges transferred from the third-first pixel PX3-1g, the third-second pixel PX3-2g, the third-third pixel PX3-3g, the third-fourth pixel PX3-4g, the third-fifth pixel PX3-5g, the third-sixth pixel PX3-6g, the third-seventh pixel PX3-7g, the third-eighth pixel PX3-8g, the third-ninth pixel PX3-9g, the third-tenth pixel PX3-10g, the third-eleventh pixel PX3-11g, the third-twelfth pixel PX3-12g, the third-thirteenth pixel PX3-13g, and the third-fourteenth pixel PX3-14g.

For example, the HDR circuit (e.g., 400a in FIG. 20) may perform the HDR merging operation based on the first-first digital signal DS1-1g, the second-first digital signal DS2-1g, and the third-first digital signal DS3-1g. The HDR merging operation may be performed between the second-first pixel PX2-1g and all of the pixels included in the first pixel group 100g. Since the number of pixels included in the first pixel group 100g is sixteen, FIGS. 23A, 23B, and 23C illustrate a 1:16 HDR merging operation. However, example embodiments are not limited thereto, and the HDR merging operation with various ratios may be performed.

FIG. 24 is a block diagram illustrating an image sensor according to example embodiments.

Referring to FIG. 24, an image sensor 500a may include a pixel array 510, a row driver 520, and a readout block 525. The image sensor 500a may further include an image processing unit 550, a ramp signal generator 560, and a timing controller 580.

Except for additionally including the row driver 520, the image processing unit 550, the ramp signal generator 560, and the timing controller 580, the image sensor 500a may be substantially the same as the image sensor 10 of FIG. 2.

The row driver 520 may be connected to a plurality of rows RW1 to RWX of the pixel array 510 and may generate drive signals for driving the plurality of rows RW1 to RWX. For example, the row driver 520 may drive a plurality of unit pixels PX included in the pixel array 510 on a row-by-row basis.

The image processing unit 550 may perform an image processing operation based on a plurality of output signals CNT1 to CNTY. For example, the image processing unit 550 may synthesize the plurality of output signals CNT1 to CNTY to generate a single image signal.

Meanwhile, in cases where the image processing unit 550 is not included, i.e., in the image sensor 10 of FIG. 2, the image processing operation and/or the image correction operation may be performed by the external processor.

The ramp signal generator 560 generates a ramp signal VRAMP that decreases or increases at a constant slope.

The timing controller 580 may control the overall operation timing of the image sensor 500a. For example, the timing controller 580 may control operations of the row driver 520, the ramp signal generator 560, and the like.

The example embodiments may be applied to various electronic devices and systems that include the image sensor. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of operating an image sensor including a pixel array, the pixel array including a plurality of first pixels, a plurality of second pixels, a plurality of third pixels and a plurality of floating diffusions, the method comprising:
outputting a plurality of first reset signals by resetting the plurality of floating diffusions in a first reset period;
outputting a plurality of first digital signals based on the plurality of first reset signals and a plurality of first pixel signals in a first signal period, the plurality of first pixel signals being outputted from the plurality of first pixels;
outputting a plurality of second reset signals by resetting the plurality of floating diffusions in a second reset period;
outputting a plurality of second digital signals based on the plurality of second reset signals and a plurality of second pixel signals in a second signal period, the plurality of second pixel signals being outputted from the plurality of second pixels;
outputting a plurality of third digital signals based on the plurality of second reset signals and a plurality of third pixel signals in a third signal period, the plurality of third pixel signals being outputted from the plurality of second pixels and the plurality of third pixels;
performing an auto focus (AF) operation based on the plurality of first digital signals and the plurality of second digital signals; and
performing a high dynamic range (HDR) merging operation based on the plurality of first digital signals, the plurality of second digital signals, and the plurality of third digital signals, and
wherein at least one of the plurality of first pixels, at least one of the plurality of second pixels, and at least one of the plurality of third pixels are configured to share one of the plurality of floating diffusions.

2. The method of claim 1, wherein the AF operation and the HDR merging operation are performed simultaneously.

3. The method of claim 2, wherein at least a portion of a first time interval in which the AF operation is performed and at least a portion of a second time interval in which the HDR merging operation is performed overlap.

4. The method of claim 1, wherein performing the HDR merging operation includes:
outputting a plurality of merging digital signals by merging the plurality of first digital signals and the plurality of third digital signals; and
outputting a plurality of result signals by merging the plurality of merging digital signals and the plurality of second digital signals.

5. The method of claim 1, wherein outputting the plurality of first reset signals includes:
outputting a ramp signal that decreases or increases at a constant slope;
resetting the plurality of floating diffusions by turning on a plurality of reset transistors included in the pixel array;
outputting a plurality of first analog reset signals based on the plurality of floating diffusions that have been reset; and
obtaining the plurality of first reset signals corresponding to a time point at which the ramp signal and the plurality of first analog reset signals intersect.

6. The method of claim 5, wherein outputting the plurality of first digital signals includes:
outputting the ramp signal;
transferring first photocharges to the plurality of floating diffusions by turning on a plurality of first transfer transistors included in the plurality of first pixels, the first photocharges being generated in the plurality of first pixels;
outputting a plurality of first analog pixel signals based on the first photocharges transferred to the plurality of floating diffusions;
outputting the plurality of first pixel signals corresponding to a time point at which the ramp signal and the plurality of first analog pixel signals intersect; and
obtaining the plurality of first digital signals based on the plurality of first reset signals and the plurality of first pixel signals.

7. The method of claim 1, wherein outputting the plurality of second reset signals includes:
outputting a ramp signal that decreases or increases at a constant slope;
resetting the plurality of floating diffusions by turning on a plurality of reset transistors included in the pixel array;
outputting a plurality of second analog reset signals based on the plurality of floating diffusions that have been reset; and
obtaining the plurality of second reset signals corresponding to a time point at which the ramp signal and the plurality of second analog reset signals intersect.

8. The method of claim 7, wherein outputting the plurality of second digital signals includes:
outputting the ramp signal;
transferring second photocharges to the plurality of floating diffusions by turning on a plurality of second transfer transistors included in the plurality of second pixels, the second photocharges generated in the plurality of second pixels;
outputting a plurality of second analog pixel signals based on the second photocharges transferred to the plurality of floating diffusions;
outputting the plurality of second pixel signals corresponding to a time point at which the ramp signal and the plurality of second analog pixel signals intersect; and
obtaining the plurality of second digital signals based on the plurality of second reset signals and the plurality of second pixel signals.

9. The method of claim 8, wherein outputting the plurality of third digital signals includes:
outputting the ramp signal;
transferring third photocharges to the plurality of floating diffusions by turning on a plurality of third transfer transistors included in the plurality of third pixels, the third photocharges generated in the plurality of third pixels;
outputting a plurality of third analog pixel signals based on the second photocharges and the third photocharges transferred to the plurality of floating diffusions;
outputting the plurality of third pixel signals corresponding to a time point at which the ramp signal and the plurality of third analog pixel signals intersect; and
obtaining the plurality of third digital signals based on the plurality of second reset signals and the plurality of third pixel signals.

10. The method of claim 1, wherein a first-first pixel among the plurality of first pixels, a second-first pixel among the plurality of second pixels, and a third-first pixel and a third-second pixel among the plurality of third pixels are configured to form a first pixel group such that a first floating diffusion among the plurality of floating diffusions and a first microlens are shared by the first-first pixel, the second-first pixel, the third-first pixel and the third-second pixel, and
wherein the first pixel group is configured to output a first-first digital signal among the plurality of first digital signals, a second-first digital signal among the plurality of second digital signals, and a third-first digital signal among the plurality of third digital signals.

11. The method of claim 1, wherein a first-first pixel among the plurality of first pixels, a second-first pixel among the plurality of second pixels, and a third-first pixel and a third-second pixel among the plurality of third pixels are configured to form a first pixel group such that a first floating diffusion among the plurality of floating diffusions and a first microlens are shared by the first-first pixel, the second-first pixel, the third-first pixel and the third-second pixel,
wherein a second-second pixel among the plurality of second pixels, and a third-third pixel, a third-fourth pixel and a third-fifth pixel among the plurality of third pixels are configured to form a second pixel group such that a second floating diffusion among the plurality of floating diffusions is shared by the second-second pixel, the third-third pixel, the third-fourth pixel and the third-fifth pixel, and
wherein the first pixel group and the second pixel group are configured to output a first-first digital signal among the plurality of first digital signals, a second-first digital signal and a second-second digital signal among the plurality of second digital signals, and a third-first digital signal and a third-second digital signal among the plurality of third digital signals.

12. The method of claim 1, wherein a first-first pixel, a first-second pixel, a first-third pixel and a first-fourth pixel among the plurality of first pixels, a second-first pixel, a second-second pixel, a second-third pixel and a second-fourth pixel among the plurality of second pixels, and a third-first pixel, a third-second pixel, a third-third pixel, a third-fourth pixel, a third-fifth pixel, a third-sixth pixel, a third-seventh pixel and a third-eighth pixel among the plurality of third pixels are configured to form a first pixel group such that a first floating diffusion among the plurality of floating diffusions is shared by the first-first pixel, the first-second pixel, the first-third pixel, the first-fourth pixel, the second-first pixel, the second-second pixel, the second-third pixel, the second-fourth pixel, the third-first pixel, the third-second pixel, the third-third pixel, the third-fourth pixel, the third-fifth pixel, the third-sixth pixel, the third-seventh pixel and the third-eighth pixel,
wherein a first microlens is shared by the first-first pixel, the first-second pixel, the second-first pixel and the second-second pixel,
wherein a second microlens is shared by the third-first pixel, the third-second pixel, the third-third pixel and the third-fourth pixel,
wherein a third microlens is shared by the third-fifth pixel, the third-sixth pixel, the third-seventh pixel and the third-eighth pixel,
wherein a fourth microlens is shared by the first-third pixel, the first-fourth pixel, the second-third pixel and the second-fourth pixel, and
wherein the first pixel group is configured to output a first-first digital signal among the plurality of first digital signals, a second-first digital signal among the plurality of second digital signals, and a third-first digital signal among the plurality of third digital signals.

13. The method of claim 1, wherein a first-first pixel and a first-second pixel among the plurality of first pixels, a second-first pixel and a second-second pixel among the plurality of second pixels, and a third-first pixel, a third-second pixel, a third-third pixel and a third-fourth pixel among the plurality of third pixels are configured to form a first pixel group such that a first floating diffusion among the plurality of floating diffusions is shared by the first-first pixel, the first-second pixel, the second-first pixel, the second-second pixel, the third-first pixel, the third-second pixel, the third-third pixel and the third-fourth pixel,
wherein a first microlens is shared by the first-first pixel and the first-second pixel, and a second microlens is shared by the third-first pixel and the third-second pixel,
wherein a third microlens is shared by the third-third pixel and the third-fourth pixel, and a fourth microlens is shared by the first-second pixel and the second-second pixel, and
wherein the first pixel group is configured to output a first-first digital signal among the plurality of first digital signals, a second-first digital signal among the plurality of second digital signals, and a third-first digital signal among the plurality of third digital signals.

14. An image sensor comprising:
a pixel array including a plurality of first pixels, a plurality of second pixels, a plurality of third pixels and a plurality of floating diffusions, the pixel array configured to output a plurality of first reset signals by resetting the plurality of floating diffusions in a first reset period, to output a plurality of first analog pixel signals in a first signal period, to output a plurality of second reset signals by resetting the plurality of floating diffusions in a second reset period, to output a plurality of second analog pixel signals in a second signal period, and to output a plurality of third analog pixel signals in a third signal period, the plurality of first analog pixel signals being outputted from the plurality of first pixels, the plurality of second analog pixel signals being outputted from the plurality of second pixels, the plurality of third analog pixel signals being outputted from the plurality of second pixels and the plurality of third pixels;
an analog-to-digital converter configured to output a plurality of first digital signals based on the plurality of first analog reset signals and the plurality of first analog pixel signals, to output a plurality of second digital signals based on the plurality of second analog reset signals and the plurality of second analog pixel signals, and to output a plurality of third digital signals based on the plurality of second analog reset signals and the plurality of third analog pixel signals;
an auto focus (AF) circuit configured to perform an AF operation based on the plurality of first digital signals and the plurality of second digital signals; and
a high dynamic range (HDR) circuit configured to perform an HDR merging operation based on the plurality of first digital signals, the plurality of second digital signals, and the plurality of third digital signals, and
wherein at least one of the plurality of first pixels, at least one of the plurality of second pixels, and at least one of the plurality of third pixels are configured to share one of the plurality of floating diffusions.

15. The image sensor of claim 14, wherein the AF operation performed by the AF circuit and the HDR merging operation performed by the HDR circuit are performed simultaneously.

16. The image sensor of claim 14, wherein the HDR circuit includes:
a first merging circuit configured to output a plurality of merging digital signals by merging the plurality of first digital signals and the plurality of third digital signals; and
a second merging circuit configured to output a plurality of result signals by merging the plurality of merging digital signals and the plurality of second digital signals.

17. The image sensor of claim 14, wherein the plurality of first pixels include a plurality of first photodiodes configured to generate photocharges based on an incident light, and a plurality of first transfer transistors connected to the plurality of first photodiodes, and the plurality of first transfer transistors are configured to transfer the photocharges to the plurality of floating diffusions,
wherein the plurality of second pixels include a plurality of second photodiodes configured to generate the photocharges based on the incident light, and a plurality of second transfer transistors connected to the plurality of second photodiodes, and the plurality of second transfer transistors are configured to transfer the photocharges to the plurality of floating diffusions, and
wherein the plurality of third pixels include a plurality of third photodiodes configured to generate the photocharges based on the incident light, and a plurality of third transfer transistors connected to the plurality of third photodiodes, and the plurality of third transfer transistors are configured to transfer the photocharges to the plurality of floating diffusions.

18. The image sensor of claim 17, wherein, when the plurality of first transfer transistors are turned on, first photocharges accumulated in the plurality of first photodiodes are transferred to the plurality of floating diffusions,
wherein the plurality of first pixels are configured to output the plurality of first analog pixel signals based on the first photocharges, and
wherein the analog-to-digital converter is configured to output the plurality of first digital signals based on:
a plurality of first reset signals corresponding to a time point at which a ramp signal that decreases or increases at a constant slope and the plurality of first analog reset signals intersect; and
a plurality of first pixel signals corresponding to a time point at which the ramp signal and the plurality of first analog pixel signals intersect.

19. The image sensor of claim 17, wherein, when the plurality of second transfer transistors are turned on, second photocharges accumulated in the plurality of second photodiodes are transferred to the plurality of floating diffusions,
wherein the plurality of second pixels are configured to output the plurality of second analog pixel signals based on the second photocharges, and
wherein the analog-to-digital converter is configured to output the plurality of second digital signals based on:
a plurality of second reset signals corresponding to a time point at which a ramp signal that decreases or increases at a constant slope and the plurality of second analog reset signals intersect; and
a plurality of second pixel signals corresponding to a time point at which the ramp signal and the plurality of second analog pixel signals intersect.

20. The image sensor of claim 19, wherein, when the plurality of third transfer transistors are turned on, third photocharges accumulated in the plurality of third photodiodes are transferred to the plurality of floating diffusions,
wherein the plurality of third pixels are configured to output the plurality of third analog pixel signals based on the second photocharges and the third photocharges, and
wherein the analog-to-digital converter is configured to output the plurality of third digital signals based on a plurality of third pixel signals corresponding to a time point at which the ramp signal and the plurality of third analog pixel signals intersect.
